(19) United States
(12) Patent Application Publication
(10) Pub. No.: US 2026/0276946 A1
(43) Pub. Date: Sep. 17, 2026

(54) MEMS WITH CURVED MIRRORS AND METHODS OF MANUFACTURE

(71) Applicant: CALIENT.AI INC., Goleta, CA (US)

(72) Inventor: Andrew HOCKING, Ithaca, NY (US)

(73) Assignee: CALIENT.AI INC., Goleta, CA (US)

(21) Appl. No.: 19/557,268

(22) Filed: Mar. 5, 2026

Related U.S. Application Data
(60) Provisional application No. 63/769,956, filed on Mar. 11, 2025.

(51) Int. Cl. G02B 7/188; B81C 1/00; G02B 5/10

(52) U.S. Cl. CPC G02B 7/188; B81C 1/00531; G02B 5/10; B81C 2201/0132; B81C 2201/019

(57) ABSTRACT

This disclosure describes a small MEMS mirror whose surface shape can be adjusted as needed. The mirror sits on a thin flexible membrane, which is held by flexures in a frame and supported from below by a post so that it can bend in a controlled way. Electrodes placed under and around the membrane apply voltages that pull on the membrane and change the mirror from its built-in curved shape toward flatter or oppositely curved shapes. Separate electrical paths run through different flexures so the voltages to the movable mirror side and the fixed electrode side stay isolated, allowing independent, stable, and precise control of the mirror curvature.

### CROSS REFERENCE TO RELATED APPLICATIONS

This U.S. patent application claims priority under 35 U.S.C. § 119(e) to U.S. Provisional Application 63/769,956, filed on Mar. 11, 2025. The disclosure of this prior application is considered part of the disclosure of this application and is hereby incorporated by reference in its entirety.

### BACKGROUND

Technical Field: This disclosure generally relates to Micro-Electro-Mechanical Systems (MEMS), and more particularly to MEMS devices incorporating reflective elements with curved surfaces, actuation mechanisms for controlling surface curvature, and methods of manufacturing such devices.

Background: Micro-Electro-Mechanical Systems (MEMS) devices integrate micro-scale mechanical structures with electrical circuitry using integrated circuit (IC) fabrication techniques. One specific type of MEMS device is a microscopic gimbaled mirror device. The gimbaled mirror device features a mirror component suspended off a wafer. The mirror component pivots about a gimbal via electrostatic actuation. Electrostatic actuation generates an electric field to pivot the mirror component. Pivoting the mirror component provides an angular range of motion, allowing the mirror component to direct or re-direct light beams (e.g., light signals) to varying positions.

An optical circuit switch is a switching device that couples light beams from an input fiber, such as an input fiber optic cable, to an output fiber, such as an output fiber optic cable. Typically, the optical circuit switch collimates and directs light beams from the input fiber toward a target location, such as the output fiber. A movable mirror, for example a gimbaled mirror within a switch mirror array, directs or redirects the light beams to the desired locations.

U.S. Pat. No. 6,753,638, entitled “Electrostatic Actuator for Micromechanical Systems,” discloses an electrostatically actuated microscopic gimbaled mirror suitable for an optical circuit switch. The actuator described in the '638 patent includes a stage with a surface and a first blade coupled to the stage, where the first blade extends perpendicular to the surface of the stage. The actuator also includes a frame with a surface and a second blade coupled to the frame. The stage pivotally couples to the frame. The second blade extends perpendicularly to the surface of the frame and remains parallel to the first blade.

FIGS. 1A and 1B illustrate a blade actuator 100 described in U.S. Pat. No. 6,753,638, which includes a stage 140, also referred to as a mirror stage, and a frame 135. An x-y-z coordinate system is shown with z normal to the wafer (i.e. positive and upward from the wafer surface). In FIG. 1A, the stage 140 is positioned parallel to the frame 135, whereas in FIG. 1B, the stage 140 is tilted relative to the frame 135. The stage 140 may include a reflective element 145, such as a mirror, disposed on a top surface of the stage 140. Flexures 153 and 154, also referred to as “springs,” pivotally couple the stage 140 to the frame 135 on diametrically opposed sides of the stage 140. The flexures 153 and 154 suspend the stage 140 within a cavity formed by the frame 135, allowing the stage 140 to pivot about a rotational axis defined by the flexures 153 and 154. Both the stage 140 and the frame 135 include one or more blades, such as blades 120 and 125, respectively, coupled to and extending from the stage 140 and the frame 135. In particular, the blade 120 is coupled to the stage 140 and the blade 125 is coupled to the frame 135. The blade 120 extends substantially perpendicular to the stage 140 (e.g., perpendicular to an undersurface of the stage 140), while the blade 125 extends substantially perpendicular to the frame 135 (e.g., perpendicular to an undersurface of the frame 135). Applying a voltage difference between the blade 120 and the blade 125 generates an electrostatic attraction that pulls the blade 120 toward the blade 125, thereby tilting (e.g., pivoting or turning) the stage 140. As the stage 140 tilts, the reflective element 145 on the stage 140 pivots correspondingly.

Flexures 151 and 152, also referred to as “springs,” similarly pivotally couple the frame 135 to an outer stationary frame (not shown) on diametrically opposed sides of the frame 135. The outer frame may function as a stationary structure or may itself move relative to yet another outer frame structure. The flexures 151 and 152 suspend the frame 135 within a cavity formed by the outer frame, allowing the frame 135 to pivot about a rotational axis defined by the flexures 151 and 152. The flexures 151 and 152 are aligned orthogonally to the flexures 153 and 154, enabling a reflective element coupled to the stage 140 to pivot in two dimensions, such as roll and pitch. As described, the blade 120 extends substantially perpendicular to the stage 140 (e.g., perpendicular to an undersurface of the stage 140), while the blade 125 extends substantially perpendicular to the frame 135 (e.g., perpendicular to an undersurface of the frame 135). An electric potential applied between the blade 120 and the blade 125 produces an electrostatic attraction between the blade 120 and the blade 125. Because the blade 120 is coupled to the stage 140, attraction of the blade 120 toward the blade 125 causes the stage 140 to pivot about the rotational axis defined by the flexures 153 and 154. Consequently, the stage 140 and the blades coupled to the stage 140 pivot such that a surface of the stage 140 is oriented at an angle relative to a surface of the frame 135, as illustrated in FIG. 1B.

FIG. 1C illustrates the suspended frame 135, the flexures 153 and 154, and the mirror stage 140. FIG. 1C presents a cross-sectional view of a MEMS device, or a MEMS actuator, fabricated from a silicon-on-insulator (SOI) wafer (also referred to as SOI substrate). The SOI wafer includes a device layer having cavities, a handle layer, and a buried oxide (BOX) layer positioned between the device layer and the handle layer. The device layer comprises a top portion, upper portion, or top sub-layer (e.g., a top silicon portion) and a bottom portion, lower portion, or bottom sub-layer (e.g., a bottom silicon portion).

Fabrication of the blades 120 utilizes the handle layer of the SOI wafer, with the BOX layer separating the handle layer from the device layer. The flexures 153 and 154 may generally include the top portion of the device layer. In this example, the flexures 153 and 154 include the top portion of the device layer but exclude the bottom portion of the device layer.

The MEMS devices described with reference to FIGS. 1A-1C employ the mirror layer 145 that provides a substantially flat mirror surface.

FIG. 1D depicts an optical circuit switch 700 that includes two MEMS mirror arrays 730 and 740. A first module 710 holds input optical fibers, and a second module 720 holds output optical fibers. In operation, light from an input fiber 712 of the first module 710 is focused by a first lens 762 onto a first mirror 732 (a mirror actuator) of the first MEMS mirror array 730. Tilting (e.g., rotating, pivoting) the first mirror 732 directs the light to a selected second mirror 742 of the second MEMS mirror array 740. The light then passes through a second lens 772, which focuses the light into an output fiber 722 of the second module 720. By adjusting the tilt of the first mirror 732, the system selects which second mirror 742 and second lens 772 the beam reaches, thereby determining which output fiber 722 of the second module 720 receives the light. Because the beam diverges along an optical path, careful selection of lens parameters is used to reduce optical loss in the system.

Targeting different output fibers changes which mirrors participate in routing and correspondingly modifies both a length and a direction of an optical path 750. These path variations alter ideal lens settings for maximizing coupling efficiency, yet in practice a lens system cannot be individually optimized for every possible path and are therefore configured around an average or representative case. Nonetheless, technical problems related to light diffusion and optical loss arise.

A technical need therefore exists for MEMS mirrors that effectively manage light diffusion and reduce signal loss. To address this need, the present disclosure describes a MEMS mirror with a static curvature set during fabrication to enhance its beam-focusing capability. In addition, the present disclosure provides a MEMS mirror whose curvature can be dynamically adjusted in response to applied voltages. Such dynamic control enables active optimization of light diffusion, thereby reducing optical loss and improving performance across multiple varying optical paths within the optical circuit switch.

### SUMMARY

To address the identified technical problems, a curved mirror (e.g., mirror with an upward-concave “U” curvature) having a fixed or dynamically adjustable curvature is disclosed. The curved mirror introduces additional design variables that can be used to reduce optical loss. As a result, mirror properties (e.g., mirror curvature of the first mirror 732 in FIG. 1D, mirror curvature of the second mirror 742 in FIG. 1D) and lens properties can be selected together to reduce or minimize signal loss.

One aspect of the disclosure provides an adjustable-curvature micro-electro-mechanical systems (MEMS) mirror device. The device includes a frame and a mirror stage coupled to the frame via a plurality of flexures including a first flexure and a second flexure, the mirror stage comprising a membrane layer and a mirror layer disposed on the membrane layer. The mirror stage is supported by a mirror post mount and a mirror post extending from the mirror post mount. A bottom electrode has an upper portion disposed adjacent to an underside of the membrane layer. The first flexure is electrically coupled to the membrane layer and the second flexure is electrically coupled to the bottom electrode, and a first voltage supplied to the first flexure and a second voltage supplied to the second flexure are routed through mutually isolated conductive paths such that the first voltage is insulated from the second voltage.

Implementations of the disclosure may include one or more of the following optional features. In some implementations, the bottom electrode is formed from a device layer of a silicon-on-insulator wafer and defines a hollow vertical structure surrounding the mirror post mount with a lower end disposed on a buried oxide layer of the silicon-on-insulator wafer. In some implementations, an upper portion of the bottom electrode is disposed adjacent to an outer edge region of the membrane layer such that the bottom electrode overlaps the membrane layer in a vertical direction to form a parallel-plate actuator. In some examples, a voltage difference between the membrane layer and the bottom electrode generates an electrostatic force that draws the membrane layer toward the bottom electrode to reduce an initial upward-concave curvature of the mirror layer and/or to change the initial upward-concave curvature of the mirror layer to a downward-concave curvature.

In some implementations, the mirror stage further includes one or more stress-engineering layers configured to impart an initial upward-concave curvature to the mirror layer. For example, a tensile stress layer may be disposed between the membrane layer and the mirror layer, a tensile stress layer may be disposed on an upper surface of the mirror layer, and/or a compressive stress layer may be disposed on an underside of the membrane layer. In some implementations, a first conductive routing path is configured to deliver the first voltage to the membrane layer via a metal trace on the frame, a contact extending through a top oxide layer, the first flexure, and a vertical interconnect extending through a buried oxide layer to a mirror post mount that is electrically coupled to the membrane layer. In some implementations, a second conductive routing path is configured to deliver the second voltage to the bottom electrode via a metal trace on the frame, a contact extending through a top oxide layer, the second flexure, and one or more vertical interconnects extending through a buried oxide layer.

Another aspect of the disclosure provides an adjustable-curvature MEMS mirror device including a comb-finger actuator. The device includes a frame and a mirror stage coupled to the frame via a plurality of flexures including a first flexure and a second flexure, the mirror stage comprising a membrane layer and a mirror layer disposed on the membrane layer. A plurality of first fingers extends outwardly from the membrane layer. A mirror post mount and a mirror post extend from the mirror post mount to support the mirror stage, and a comb mount surrounds the mirror post mount. A plurality of second fingers extends inwardly from an upper portion of the comb mount and is interdigitated with the plurality of first fingers to form the comb-finger actuator. The first flexure is electrically coupled to the membrane layer and the plurality of first fingers, the second flexure is electrically coupled to the comb mount and the plurality of second fingers, and a first voltage supplied to the first flexure and a second voltage supplied to the second flexure are routed through mutually isolated conductive paths such that the first voltage is insulated from the second voltage.

Implementations of the comb-finger actuator may include one or more of the following features. In some implementations, each of the plurality of first fingers and the plurality of second fingers has a width between approximately 1.5 μm and 3.0 μm and a gap between adjacent ones of the plurality of first fingers and the plurality of second fingers between approximately 2.0 μm and 3.0 μm. In some implementations, a thickness of the plurality of second fingers corresponds to a thickness of a device layer of a silicon-on-insulator wafer or to a thickness of an upper portion of a device layer of a silicon-on-insulator wafer, and in some examples the plurality of second fingers, the plurality of first fingers, and the membrane layer each has substantially the same thickness. In some implementations, the membrane layer has an initial upward-concave curvature with a radius of curvature between approximately 10 mm and 15 mm such that the plurality of first fingers is vertically offset relative to the plurality of second fingers by approximately 0.5 μm to 2 μm, and the plurality of first fingers and the plurality of second fingers are arranged to surround at least a substantial portion of an outer perimeter of the membrane layer and a corresponding inner perimeter of the comb mount.

In operation, when the first voltage and the second voltage establish a potential difference between the plurality of first fingers and the plurality of second fingers, an electrostatic force generated between the plurality of first fingers and the plurality of second fingers displaces the membrane layer to reduce an initial upward-concave curvature of the mirror layer and/or to change the initial upward-concave curvature of the mirror layer to a downward-concave curvature. In some implementations, the mirror stage further comprises one or more stress-engineering layers, such as a tensile stress layer between the membrane layer and the mirror layer, a tensile stress layer on an upper surface of the mirror layer, and/or a compressive stress layer on an underside of the membrane layer, configured to impart the initial upward-concave curvature to the mirror layer in the absence of actuation of the comb-finger actuator.

A further aspect of the disclosure provides an adjustable-curvature MEMS mirror device including a comb-finger actuator with a parallel-plate assistance electrode. The device includes a frame and a mirror stage coupled to the frame via a plurality of flexures including a first flexure and a second flexure, the mirror stage comprising a membrane layer and a mirror layer disposed on the membrane layer. A plurality of first fingers extends outwardly from the membrane layer. A mirror post mount and a mirror post extend from the mirror post mount to support the mirror stage. A comb mount surrounds the mirror post mount, and a plurality of second fingers extends inwardly from an upper portion of the comb mount and is interdigitated with the plurality of first fingers to form the comb-finger actuator. A parallel-plate assistance electrode surrounds the mirror post mount and is disposed beneath at least a portion of the membrane layer. The first flexure is electrically coupled to the membrane layer and the plurality of first fingers, the second flexure is electrically coupled to the parallel-plate assistance electrode, the comb mount, and the plurality of second fingers, and a first voltage supplied to the first flexure and a second voltage supplied to the second flexure are routed through mutually isolated conductive paths such that the first voltage is insulated from the second voltage.

Implementations of the comb-finger actuator with parallel-plate assistance may include one or more of the following optional features. In some implementations, the parallel-plate assistance electrode includes a hollow peripheral body surrounding the mirror post mount and defining an inner opening in which the mirror post mount is disposed. In some implementations, the parallel-plate assistance electrode includes a main body underlying an outer region of the membrane layer and a plurality of protrusions extending radially outward to underlie respective ones of the plurality of first fingers. In some examples, an upper surface of the parallel-plate assistance electrode is spaced from an underside of the membrane layer by a gap selected such that, when the second voltage is applied to the parallel-plate assistance electrode and the first voltage is applied to the membrane layer, an electrostatic parallel-plate force is generated that cooperates with an electrostatic comb-finger force between the plurality of first fingers and the plurality of second fingers to displace the membrane layer so as to reduce an initial upward-concave curvature of the mirror layer and/or change the initial upward-concave curvature of the mirror layer to a downward-concave curvature. In some implementations, the parallel-plate assistance electrode and the comb mount are electrically common and are driven at a same potential via the second flexure, and geometry and spacing of the parallel-plate assistance electrode under the membrane layer are configured such that, at an intermediate actuation level at which the mirror layer is substantially flat, the parallel-plate contribution provides a dominant portion of a net electrostatic force acting on the membrane layer.

Another aspect of the disclosure provides a method of fabricating a MEMS array. The method includes forming first etched regions on a first wafer, forming partially etched regions on a second wafer, bonding the second wafer to the first wafer, and removing at least a portion of the second wafer. The method also includes forming isolation trenches in the first wafer, filling the isolation trenches with dielectric material, forming vias in the first wafer, depositing a first metal layer on the first wafer, and depositing a second metal layer on the first wafer to form a reflective surface. The method further includes etching the first wafer to form blades, bonding a base wafer to the first wafer, and forming release trenches in the first wafer to release MEMS structures. In some implementations, the first wafer and the second wafer are silicon-on-insulator wafers, a stress layer is deposited on selected regions of the first wafer, and a lid wafer is bonded to the first wafer after forming the release trenches.

The details of one or more implementations of the disclosure are set forth in the accompanying drawings and the description below. Other aspects, features, and advantages will be apparent from the description and drawings, and from the claims.

### INCORPORATION BY REFERENCE

All publications, patents, and patent applications mentioned in this specification are herein incorporated by reference to the same extent as if each individual publication, patent, or patent application was specifically and individually indicated to be incorporated by reference, except for any definitions, disclaimers, disavowals, and inconsistencies, to the maximum extent allowable by law.
DE 19,851,967 B4 issued Dec. 22, 2005 by Laermer et al.;
U.S. Pat. No. 5,563,343 A published Oct. 8, 1996 by Shaw et al.;
U.S. Pat. No. 5,729,026 A published Mar. 17, 1998 by Mamin et al.;
U.S. Pat. No. 5,739,941 A published Apr. 14, 1998 by Knipe et al.;
U.S. Pat. No. 6,054,659 A published Apr. 25, 2000 by Lee et al.;
U.S. Pat. No. 6,201,629 B1 issued Mar. 13, 2001 by McClelland et al.;
U.S. Pat. No. 6,239,473 B1 issued May 29, 2001 by Adams et al.;
U.S. Pat. No. 6,396,620 B1 issued May 28, 2002 by Goodwin Johansson;
U.S. Pat. No. 6,701,038 B2 issued Mar. 2, 2004 by Rensing et al.;
U.S. Pat. No. 6,753,638 B2 issued Jun. 22, 2004 by Adams et al.;
U.S. Pat. No. 6,915,046 B2 issued Jul. 5, 2005 by Jin et al.;
U.S. Pat. No. 7,095,546 B2 issued Aug. 22, 2006 by Mala et al.;
U.S. Pat. No. 7,098,571 B2 issued Aug. 29, 2006 by Adams et al.;
U.S. Pat. No. 7,123,397 B2 issued Oct. 17, 2006 by Kenzi;
U.S. Pat. No. 7,196,599 B2 issued Mar. 27, 2007 by Dabbaj;
U.S. Pat. No. 7,261,826 B2 issued Aug. 28, 2007 by Adams et al.;
U.S. Pat. No. 7,411,717 B2 issued Aug. 12, 2008 by Patel et al.;
U.S. Pat. No. 7,484,857 B2 issued Feb. 3, 2009 by Bozler et al.; and
U.S. Pat. No. 7,548,145 B2 issued Jun. 16, 2009 by Rubel;
U.S. Pat. No. 7,728,339 B1 issued Jun. 1, 2010 by Adams et al.;
U.S. Pat. No. 7,952,778 B2 issued May 31, 2011 by Moidu et al.;
U.S. Pat. No. 8,115,576 B2 issued Feb. 14, 2012 by Lu et al.;
U.S. Pat. No. 8,134,277 B2 issued Mar. 13, 2012 by Moidu;
U.S. Pat. No. 8,188,634 B2 issued May 29, 2012 by Krueger et al.;
U.S. Pat. No. 8,205,268 B2 issued Jun. 19, 2012 by Shile;
U.S. Pat. No. 8,361,331 B2 issued Jan. 29, 2013 by Yang et al.;
U.S. Pat. No. 8,378,434 B2 issued Feb. 19, 2013 by Krylov et al.;
U.S. Pat. No. 8,542,445 B2 issued Sep. 24, 2013 by Boils;
U.S. Pat. No. 9,046,690 B2 issued Jun. 2, 2015 by Sabry et al.;
U.S. Pat. No. 9,086,571 B2 issued Jul. 21, 2015 by Zhou;
U.S. Pat. No. 9,164,277 B2 issued Oct. 20, 2015 by Holger et al.
U.S. Pat. No. 9,310,609 B2 issued Apr. 12, 2016 by Rueblinger et al.;
U.S. Pat. No. 9,442,285 B2 issued Sep. 13, 2016 by Rogers;
U.S. Pat. No. 9,674,627 B2 issued Jun. 6, 2017 by Hsu et al.;
U.S. Pat. No. 9,764,942 B2 issued Sep. 19, 2017 by Iihola et al.;
U.S. Pat. No. 10,274,723 B2 issued Apr. 30, 2019 by Ozaki et al.;
U.S. Pat. No. 10,291,151 B2 issued May 14, 2019 by Gutierrez;
U.S. Pat. No. 10,444,492 B2 issued Oct. 15, 2019 by Hopkins et al.;
U.S. Pat. No. 10,761,317 B2 issued Sep. 1, 2020 by Hauf et al.;
U.S. Pat. No. 10,879,869 B2 issued Dec. 29, 2020 by Elsayad et al.;
U.S. Pat. No. 11,567,312 B2 issued Jan. 31, 2023 by Zhou;
U.S. Pat. No. 11,693,233 B2 issued Jul. 4, 2023 by Baran;
U.S. Pat. No. 12,091,313 B2 issued Sep. 17, 2024 by Towfighian et al.;
US 2003/0200748 A1 published Oct. 30, 2003 by Bromley, Susan C. et al.;
US 2004/0160118 A1 published Aug. 19, 2004 by Knollenberg, Clifford F. et al.;
US 2007/0247018 A1 published Oct. 25, 2007 by Flores et al.;
US 2012/0279837 A1 published Nov. 8, 2012 by De Wolf et al.;
US 2019/0235230 A1 published Aug. 1, 2019 by Zemp et al.;
US 2021/0396992 A1 published Dec. 23, 2021 by Wang et al.;
US 2022/0269067 A1 published Aug. 25, 2022 by McDONALD et al.;
US 2023/0023348 A1 published Jan. 26, 2023 by Miller;
US 2024/0012332 A1 published Jan. 11, 2024 by HASPESLAGH et al.;
US 2024/0018549 A1 published Jan. 18, 2024 by BANERJEE;
US 2024/0094525 A1 published Mar. 21, 2024 by HOCKING;
US 2024/0295728 A1 published Sep. 5, 2024 by JIN et al.;
WO 2003/073597 A1 published Sep. 4, 2003 by KyoHo;
WO 2016/020716 A1 published Feb. 11, 2016 by BaTis et al.;
WO 2016/143804 A1 published Sep. 15, 2016 by Ozaki et al.; and
WO 2022/148698 A1 published Jul. 14, 2022 by Ameling.

### DESCRIPTION OF DRAWINGS

The novel features of the teachings are set forth with particularity in the present disclosure. As will be appreciated by those skilled in the art, the various features illustrated in the drawings may not be drawn to scale. Moreover, the illustrations presented in the present disclosure are not meant to be actual views of any particular apparatus (e.g., device, system, etc.) or method, but are merely representations that are employed to describe various examples of the disclosure. Accordingly, the dimensions of the various features may be arbitrarily expanded or reduced in the figures for clarity. In addition, some of the drawings may be simplified for clarity. Thus, the drawings may not depict all of the components of a given apparatus (e.g., device) or all operations of a particular method. The novel features of the disclosure are set forth with particularity in any claim presented.

A better understanding of the features and advantages of the present disclosure will be obtained by reference to the following detailed description that sets forth illustrative examples, in which the principles of the present disclosure are utilized, and the accompanying drawings of which:

FIG. 1A illustrates an actuator with a mirror stage parallel to a frame;

FIG. 1B illustrates an actuator with a mirror stage tilted with respect to a frame;

FIG. 1C illustrates a side view of a mirror stage;

FIG. 1D illustrates an optical circuit switch including two mirror arrays;

FIG. 2A illustrates a cross-sectional view of a mirror stage including a fixed-curvature mirror layer in accordance with some implementations of the disclosure;

FIG. 2B illustrates a detailed cross-sectional view of a mirror stage configured with a tensile-stress layer in accordance with some implementations of the disclosure;

FIG. 2C illustrates a detailed cross-sectional view of a mirror stage configured with a compressive-stress layer in accordance with some implementations of the disclosure;

FIG. 2D illustrates thermal-simulation results for a mirror stage including a fixed-curvature mirror in accordance with some implementations of the disclosure;

FIG. 3A illustrates a cross-sectional view of a mirror stage including a mirror of adjustable curvature actuated by a parallel-plate actuator in accordance with some implementations of the disclosure;

FIG. 3B illustrates a top view of a mirror stage including a mirror of adjustable curvature actuated by a parallel-plate actuator in accordance with some implementations of the disclosure;

FIG. 3C illustrates a close-up cross-sectional view of the mirror stage including a mirror of adjustable curvature actuated by a parallel-plate actuator in accordance with some implementations of the disclosure;

FIG. 4A illustrates a cross-sectional view of a mirror stage including a mirror of adjustable curvature actuated by a comb-finger actuator in accordance with some implementations of the disclosure;

FIG. 4B illustrates a top view of a mirror stage including a mirror of adjustable curvature actuated by a comb-finger actuator in accordance with some implementations of the disclosure;

FIG. 4C illustrates a cross-sectional view of a mirror stage including a mirror of adjustable curvature actuated by an array of comb fingers having a thickness similar to a thickness of a top portion of a device layer of a SOI wafer in accordance with some implementations of the disclosure;

FIGS. 4D and 4E illustrate a close-up side view and a perspective close-up view of comb fingers having a thickness similar to a thickness of a top portion of a device layer of a SOI wafer in accordance with some implementations of the disclosure;

FIG. 5A illustrates a cross-sectional view of a mirror stage including a mirror of adjustable curvature actuated by a parallel-plate-assisted comb-finger actuator in accordance with some implementations of the disclosure;

FIG. 5B illustrates a top view of a mirror stage including a mirror of adjustable curvature actuated by a parallel-plate-assisted comb-finger actuator in accordance with some implementations of the disclosure;

FIG. 5C illustrates a perspective close-up view of comb-finger actuators provided with parallel-plate assist electrodes in accordance with some implementations of the disclosure;

FIG. 5D is a graph showing force applied to a membrane layer as a function of membrane-edge displacement for different electrostatic actuation schemes;

FIG. 6A-1 illustrates a cross-section of a first SOI silicon wafer;

FIG. 6A-2 illustrates a cross-section of the first SOI silicon wafer including etched silicon trenches;

FIG. 6A-3 illustrates a cross-section of a second SOI silicon wafer;

FIG. 6A-4 illustrates a cross-section of the second SOI silicon wafer including partially etched regions;

FIG. 6A-5 illustrates a cross-section of the first and second SOI silicon wafers bonded together;

FIG. 6A-6 illustrates a cross-section of the bonded SOI wafers after removal of the handle and buried-oxide layers of the second SOI wafer;

FIG. 6B illustrates a portion of a silicon wafer resulting from the bonding, including a masking layer, a photoresist layer, and an opening to the silicon surface of the wafer;

FIG. 6C illustrates a portion of the silicon wafer including an isolation trench formed in the silicon;

FIG. 6D illustrates a portion of the silicon wafer including a dielectric layer on the top surface of the silicon wafer and on sidewalls and a bottom of the isolation trench;

FIG. 6E illustrates a portion of the silicon wafer after planarization of the dielectric layer;

FIG. 6F-1 illustrates isolation trenches on a top surface of the silicon wafer and a masking layer for blades on a bottom surface of the silicon wafer;

FIG. 6F-2 illustrates partial removal of the dielectric layer, deposition of a tensile-stress layer, and partial removal of the tensile-stress layer;

FIG. 6G illustrates metallization on a top surface of the silicon wafer;

FIG. 6H illustrates blades resulting from deep silicon etching;

FIG. 6I illustrates a base wafer bonded to a wafer including blades;

FIG. 6J illustrates trenches on a top surface of the silicon wafer that separate portions of the structure; and

FIG. 6K illustrates the silicon wafer after attachment of a lid wafer.

Like reference symbols in the various drawings indicate like elements.

### DETAILED DESCRIPTION

### I. Devices

### (a) Fixed Curvature Mirror

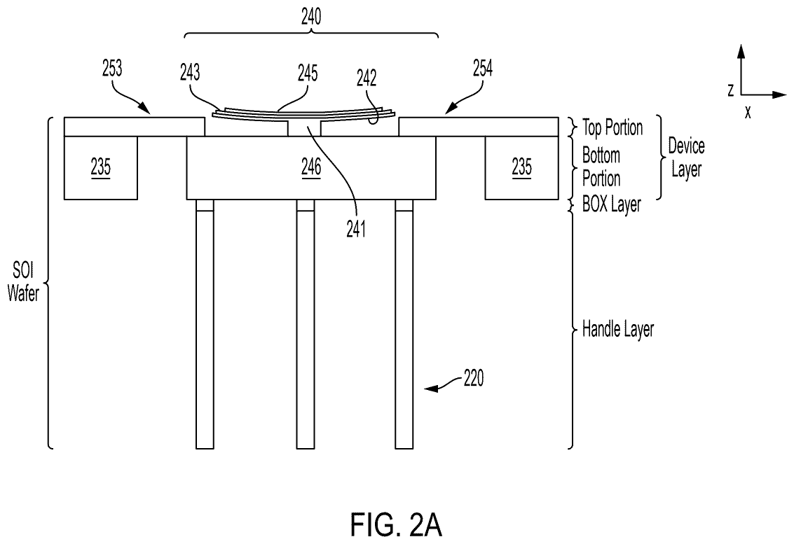

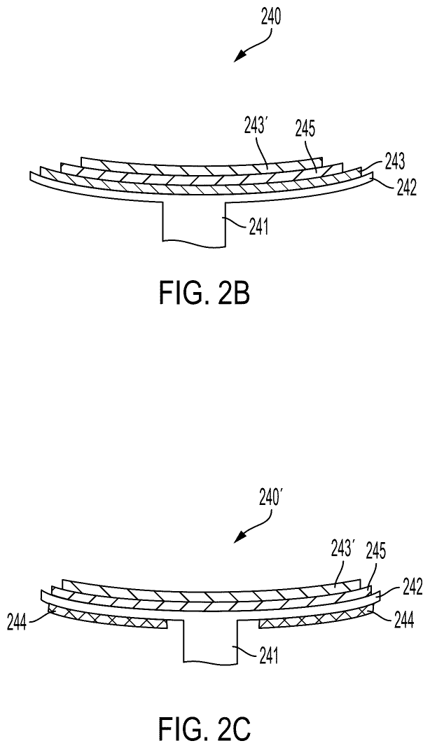

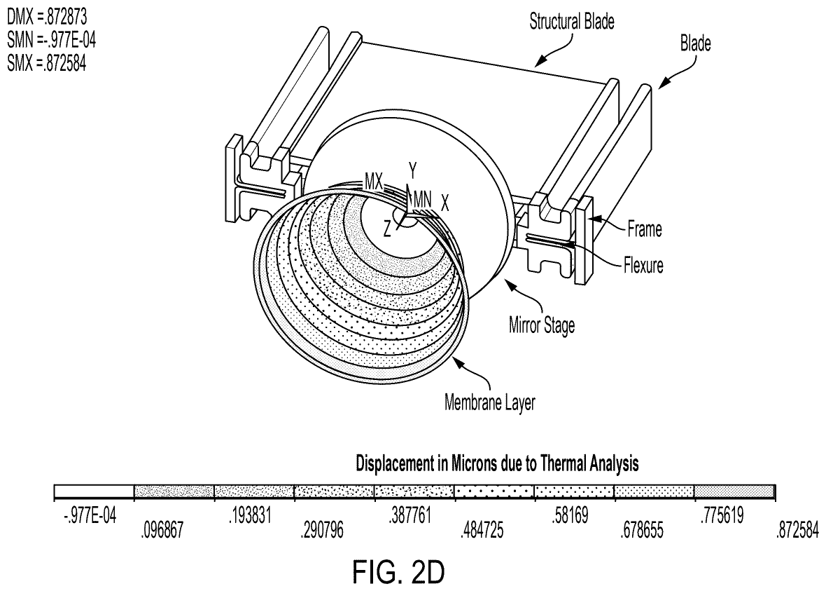

FIG. 2A illustrates a cross-sectional view of a mirror stage 240, which is coupled to a suspended frame 235 by flexures 253 and 254 in accordance with the present disclosure.

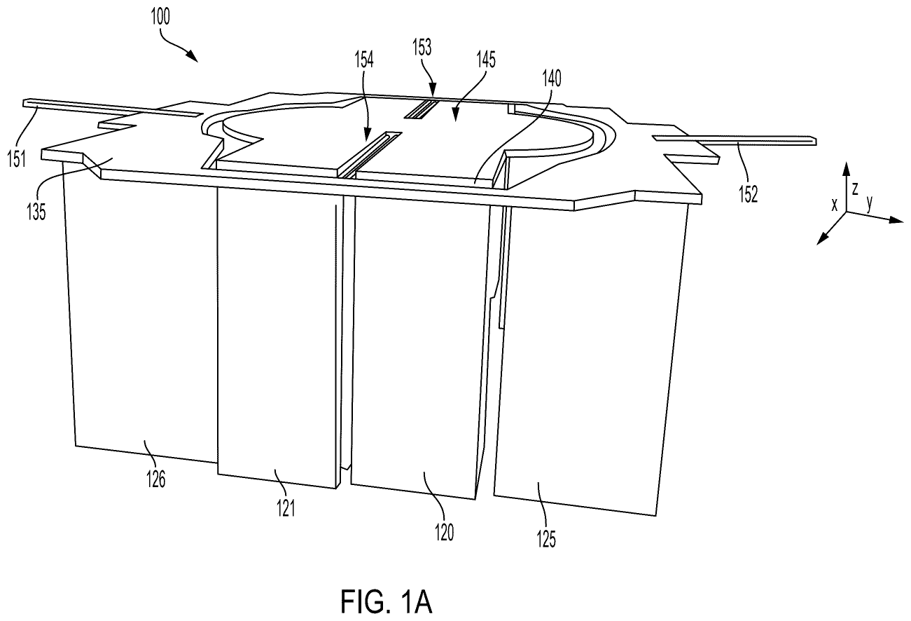

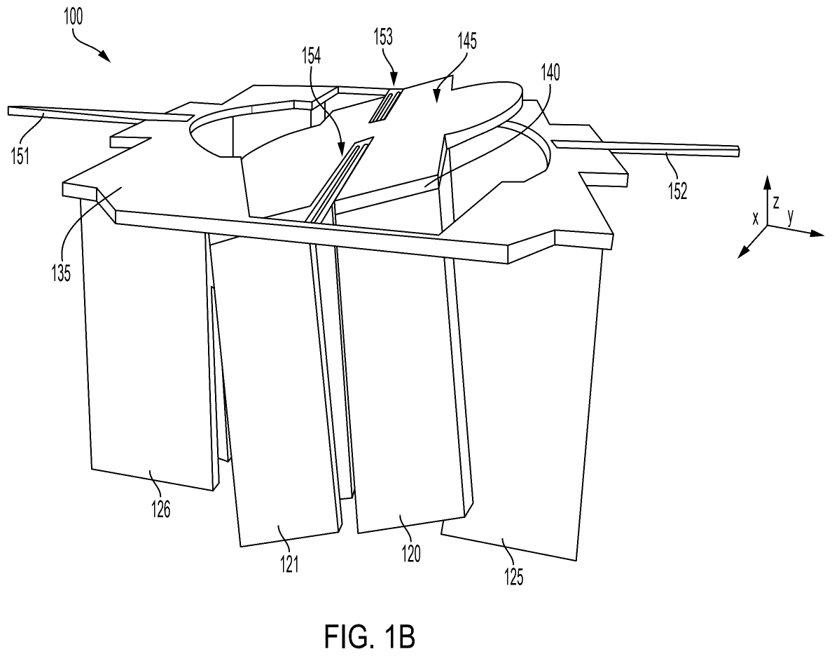

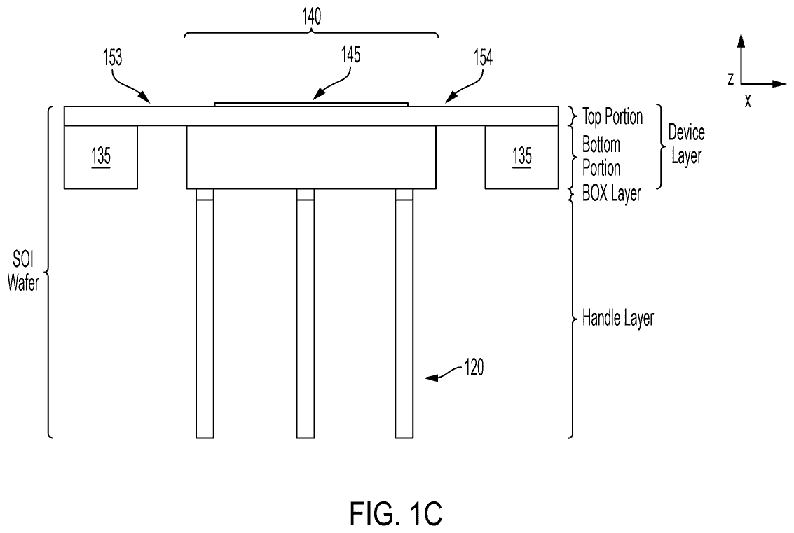

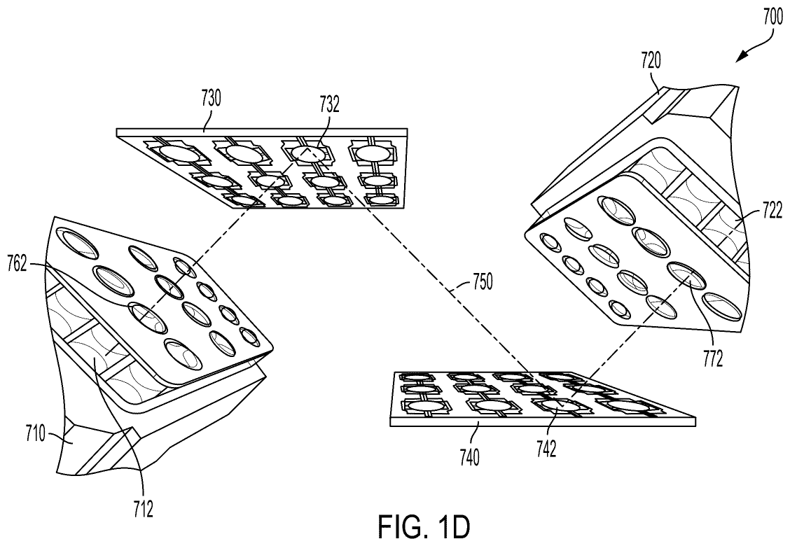

In this exemplary configuration, instead of positioning or attaching the mirror layer 145 to the top flat portion of the SOI wafer as in FIG. 1C—which keeps the mirror layer 145 flat—the mirror layer 245 in FIG. 2A (also referred to as a reflective element, reflective layer, or mirror metal) is attached to a membrane layer 242 (also referred to as a mirror membrane layer or flexible membrane layer) that may have a curvature. In this example, the curvature of the membrane layer 242 may have an upward-concave curvature (e.g., “U” or bowl-shaped curvature) due to a tensile stress layer 243, which will be described in greater detail in this disclosure.

In this non-limiting example, the mirror layer 245 is attached to the membrane layer 242 via the tensile stress layer 243 (also referred to as a tensile stress film) disposed between the membrane layer 242 and the mirror layer 245. The membrane layer 242 may have a thickness in a range including, but not limited to, between approximately 1.5 μm and 3 μm. For example, in one configuration, the membrane layer 242 has a thickness of approximately 2 μm. As shown, the membrane layer 242 acts as a structural support and can be attached to the bottom portion of a device layer (e.g., lower mirror stage 246) through a mirror post 241. In this example, the tensile-stress layer 243 imparts curvature (e.g., upward-concave curvature) to the membrane layer 242. The curvature of the membrane layer 242, in turn, causes the mirror layer 245 to curve, which may result in an upward-concave curvature. However, in some cases, the tensile stress layer 243 may be optional where the mirror layer 245 includes one or more metal layers capable of providing sufficient curvature (e.g., upward-concave curvature) to the mirror layer 245 independently.

The mirror layer 245 may include, but is not limited to, one or more metal layers (e.g., aluminum layer) configured to act as an integrated tensile stress layer that independently curves the mirror layer 245 upward into an upward-concave shape. In one non-limiting example, an aluminum layer with a thickness of approximately 10 nm may achieve a curvature having a radius of approximately 12 mm. Reducing the intrinsic stress through annealing or other suitable processes may allow for a thicker mirror layer 245, which may be advantageous for reflectivity, fabrication robustness, or other purposes.

Returning to FIG. 2A, in some implementations, the tensile stress layer 243 is disposed between the mirror layer 245 and the membrane layer 242 when one or more metal layers of the mirror layer 245 (i.e., a tensile stress layer integrated into the mirror layer 245) do not provide sufficient curvature (e.g., upward-concave curvature), or when the mirror layer 245 does not include such metal layers.

As further illustrated in FIG. 2A, blades 220 can extend from (e.g., connect to, coupled to) one or more of the lower mirror stage 246, mirror layer 245, mirror post 241, and membrane layer 242.

In other examples, the mirror layer 245 may comprise materials other than (or in addition to) aluminum, such as gold (Au), silver (Ag), or a dielectric stack, to achieve a desired reflectivity in specific wavelength ranges (e.g., infrared or visible). Similarly, the membrane layer 242 is not limited to silicon and may comprise silicon nitride (SiN), silicon carbide (SiC), a polymer material, or suitable flexible material. In such variations, the tensile stress layer 243 may be selected from a material (e.g., silicon nitride) capable of inducing the requisite tensile stress on the specific membrane and mirror materials selected.

Furthermore, the location of the tensile stress layer 243 is not limited to the interface between the mirror layer 245 and the membrane layer 242. For example, the tensile stress layer 243 may be disposed on the top surface of the mirror layer 245, provided that the tensile stress layer 243 is optically transparent (e.g., silicon nitride) at an operating wavelength or is patterned (e.g., as a ring or perimeter frame) to expose a reflective portion of the mirror layer 245. This configuration is illustrated by a tensile stress layer 243′ on the mirror layer 245 in FIG. 2B.

FIG. 2B presents a detailed cross-sectional view of the mirror stage 240 of FIG. 2A with the additional tensile stress layer 243′ described previously.

As shown, creating a curvature in the membrane layer 242 (e.g., thin flexible silicon membrane layer) consequently changes the curvature of the mirror layer 245. While the mirror layer 245 may impart tensile stress to the membrane layer 242, the mirror layer 245 alone may not achieve a desired curvature (e.g., desired upward-concave curvature) in some instances. Furthermore, the intrinsic stress of the mirror layer 245 can be reduced through annealing, thereby allowing the stress of a separate material to control the radius of curvature. Accordingly, the tensile stress layer 243 may be applied to a first surface (e.g., top surface) of the membrane layer 242 to curve both the membrane layer 242 and the mirror layer 245 upward to a desired upward-concave curvature. In this configuration, the mirror layer 245 is disposed overlying the tensile stress layer 243. The tensile stress layer 243 may comprise, for example, silicon nitride. A suitable thickness for the tensile stress layer 243 may be approximately 75 nm to achieve a radius of curvature of approximately 12 mm. Depending on the desired radius of curvature (e.g., desired radius of upward-concave curvature) and the thickness of the membrane layer 242, the thickness of the tensile stress layer 243 may range, for example, from approximately 30 nm to 240 nm.

As noted regarding FIG. 2A, the mirror layer 245 in FIG. 2B may also comprise materials other than (or in addition to) aluminum, such as gold (Au), silver (Ag), or a dielectric stack, to achieve desired reflectivity in specific wavelength ranges. Similarly, the membrane layer 242 may also comprise materials other than silicon, such as silicon nitride (SiN), silicon carbide (SiC), or a polymer material. In such variations, the tensile stress layer 243 is selected to induce the target stress on the chosen membrane and mirror materials.

Additionally, the location of the tensile stress layer 243 is not limited to the interface between the mirror layer 245 and the membrane layer 242. The tensile stress layer 243, as shown with the tensile stress layer 243′ (e.g., silicon nitride tensile stress layer), may be disposed on the top surface of the mirror layer 245, provided it is optically transparent at the operating wavelength or is patterned to expose a reflective portion of the mirror layer 245.

In this example, two tensile stress layers 243 and 243′ are used to create the desired upward-concave curvature in both the membrane layer 242 and the mirror layer 245. In some implementations, only the tensile stress layer 243 may be used to create the curvature in both the membrane layer 242 and the mirror layer 245. In some implementations, only the tensile stress layer 243′ may be used to create the curvature in both the membrane layer 242 and the mirror layer 245.

FIG. 2C presents another example of detailed cross-sectional view of a mirror stage 240′ in accordance with some implementations of the disclosure.

In FIG. 2C, the curvature of the mirror layer 245 is controlled by inducing a curvature in the underlying membrane layer 242 (e.g., thin flexible silicon membrane layer). To achieve this, a compressive stress layer 244 may be applied to a second surface (e.g., bottom surface) of the membrane layer 242, forcing both the membrane layer 242 and the mirror layer 245 to curve upward into an upward-concave curvature in this example. In this configuration, the compressive stress layer 244 includes silicon oxide (SiO₂); for example, a thickness of approximately 50 nm can be used to achieve a radius of curvature of approximately 12 mm. Depending on the target radius and the properties of the membrane layer 242, the thickness of the compressive stress layer 244 typically ranges from approximately 20 nm to 150 nm.

The compressive stress layer 244 may utilize various materials and patterns to satisfy specific optical requirements. Beyond silicon oxide, suitable materials include compressive silicon nitride, thermally grown oxide, or polymers (e.g., polyimide or parylene) processed to retain residual compressive stress. Furthermore, the compressive stress layer 244 need not cover the entire bottom surface of the membrane layer 242. It may be partially applied or patterned—for instance, into grids, concentric rings, or radial spokes—to fine-tune the curvature of the mirror layer 245.

Structural integration may also be adjusted for precise mechanical or thermal performance. For instance, the compressive stress layer 244 can be configured to either contact the mirror post 241 or be spaced apart from the mirror post 241 as shown in FIG. 2C. In more complex assemblies, a plurality of compressive layers 244 may be stacked or paired with tensile stress layers (e.g., tensile stress layer 243 and/or tensile stress layer 243′) on opposing sides. These combinations allow for the precise calibration of focal lengths and effective compensation for thermal expansion mismatches.

FIG. 2D illustrates exemplary results from a finite element analysis (FEA) thermal simulation, depicting a three-dimensional view of a mirror assembly featuring a fixed-curvature membrane layer (e.g., membrane layer 242 in FIG. 2B, membrane layer 242 in FIG. 2C).

In the illustrated simulation, the outer edge of the membrane layer exhibits a displacement of approximately 900 nm; however, it should be appreciated that this value is provided solely for illustrative purposes. Actual displacement values may vary based on specific material properties, membrane layer dimensions, and applied stress levels utilized in a given implementation.

The techniques described herein for inducing curvature in a membrane layer 242 (and thereby curving the associated mirror layer 245 to an upward-concave curvature), as generally illustrated in FIGS. 2B and 2C, may be employed individually or in combination. For example, a tensile stress layer 243 may be disposed on the first surface (e.g., topside) of the membrane layer 242, while a compressive stress layer 244 is disposed on the second, opposing surface (e.g., the bottom side). This cooperative arrangement can effectively induce or enhance an upward-concave curvature of the mirror layer 245.

Conversely, where a downward static radius of curvature (e.g., a downward-concave surface or “∩” or upside-down bowl-shaped curvature) is desired, or where fine-tuning of the upward-concave curvature of the mirror layer is required, the arrangement of the stress layers may be adapted accordingly. For instance, in various examples, the tensile stress layer 243 may be applied to the bottom side of the membrane layer 242, and/or a compressive stress layer 244 may be applied to the topside of the membrane layer 242. In some implementations, the compressive stress layer 244 may be applied to the topside of the mirror layer 245. It is to be understood that the selection of tensile stress or compressive stress layers, as well as their specific placement on either the top or bottom surfaces, may be tailored to achieve a wide range of target curvature profiles without departing from the scope of the present disclosure.

As described in greater detail below, different techniques can be used to change the surface curvature of the mirror (e.g., the mirror layer 245 having an upward-concave curvature), thereby enabling active optimization of light diffusion, reducing optical loss, and improving performance across multiple variable optical paths within the optical circuit switch.

### (b) Adjustable Curvature Mirror with Parallel Plate Actuator

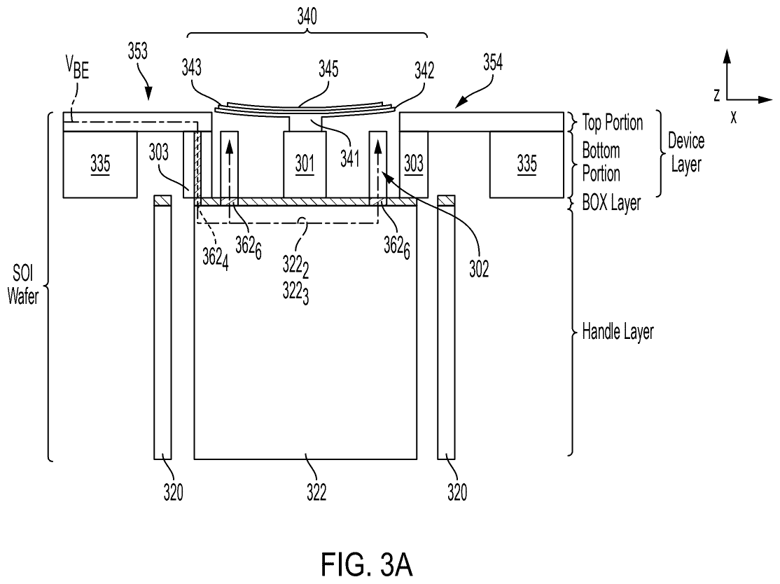

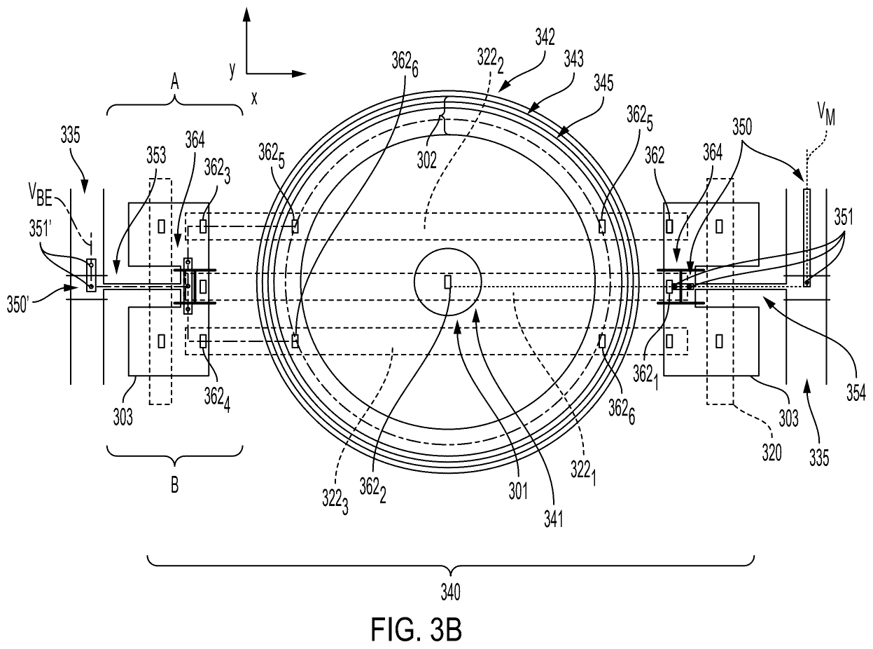

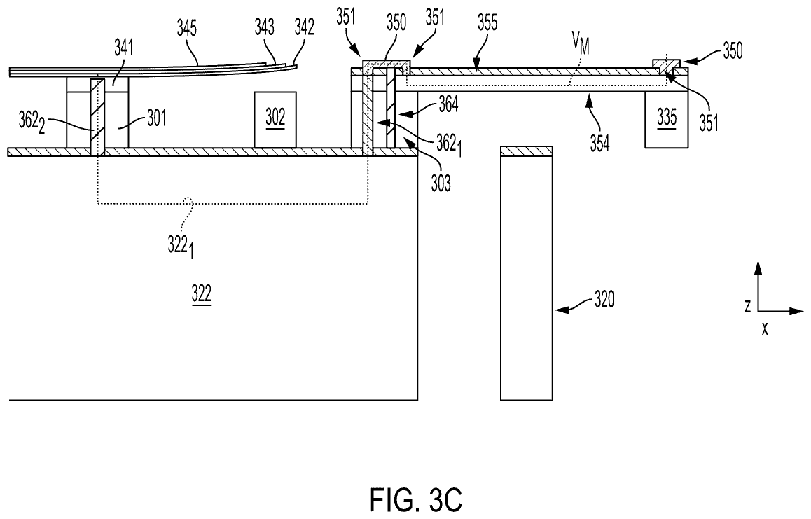

FIG. 3A illustrates a cross-sectional view of a mirror stage 340 coupled to a suspended frame 335 via flexures 353 and 354. As shown, the mirror stage 340 includes a membrane layer 342, a mirror layer 345, and a tensile stress layer 343 between the membrane layer 342 and the mirror layer 345. As described previously, in some implementations, the mirror stage 340 may include a tensile stress layer (e.g., tensile stress layer 243′ in FIG. 2B) on the upper surface of the mirror layer 345. In some implementations, the mirror stage 340 may include a compressive stress layer (e.g., compressive stress layer 244 in FIG. 2C) on the bottom side of the membrane layer 342. Any combination of a tensile stress layer between the mirror layer 345 and the membrane layer 342, a tensile stress layer on the upper surface of the mirror layer 345, and/or a compressive stress layer on the bottom side of the membrane layer 342 can be used to create an upward-concave curvature in the mirror layer 345. Also as described previously, for fine-tuning the curvature of the mirror layer 345 or to change the curvature of the mirror layer 345 to a downward-concave curvature (e.g., “∩” or upside-down bowl-shaped curvature), a tensile stress layer 343 may be disposed on the bottom side of the membrane layer 342 and/or a compressive stress layer may be disposed on the top side of the membrane layer 342.

In contrast to the fixed-curvature examples (e.g., FIGS. 2A-2C), the example shown in FIG. 3A incorporates a parallel plate actuation mechanism configured to dynamically adjust the curvature of the mirror layer 345 of the mirror stage 340 (e.g., upward-concave curvature of the mirror layer 345).

As described herein, one or more stress-inducing layers may be included to impart an initial curvature (e.g., a rest-state curvature). For example, the tensile stress layer 343 may be disposed between the membrane layer 342 and the mirror layer 345 to induce an upward-concave curvature. The tensile stress layer 343 may be disposed on top of the mirror layer 345, or both on top of the mirror layer 345 and between the membrane layer 342 and the mirror layer 345. Alternatively, or in combination, a compressive stress layer (e.g., similar to compressive stress layer 244 in FIG. 2C) may be disposed on the underside of the membrane layer 342.

In the example of FIG. 3A, the mirror layer 345 is disposed on the tensile stress layer 343, which in turn is disposed on the membrane layer 342. The tensile stress layer 343 induces an upward-concave curvature in the membrane layer 342 and the mirror layer 345. As shown, the membrane layer 342 is mechanically coupled to a mirror post mount 301 via a mirror post 341. The mirror post 341 may be formed form a device layer of the wafer (e.g., top portion of the device layer of the SOI wafer). The mirror post mount 301 may be formed from the device layer of the wafer (e.g., a bottom portion of the device layer of the SOI wafer), is mechanically and electrically coupled to a first structural blade 322₁ (shown in FIG. 3B), which is disposed between a second structural blade 322₂ and a third structural blade 322₃. In this example, the first structural blade 322₁ is coupled to a mirror stage mount 303 (on the right side) mechanically and electrically. As shown, in this example, the first structural blade 322₁, the second structural blade 322₂, and the third structural blade 322₃ are disposed between blades 320.

A bottom electrode 302 may also be formed from a device layer of a SOI wafer (e.g., a bottom portion of the device layer of the SOI wafer). The bottom electrode 302 may define a hollow vertical structure, such as an open cylinder or tube. A lower end of the bottom electrode 302 may be disposed on a buried oxide (BOX) layer of the SOI wafer. In the illustrated configuration, the mirror post mount 301 is positioned within an interior region of the bottom electrode 302 on the BOX layer, while the mirror stage mount 303 is positioned externally, adjacent to sidewalls of the bottom electrode 302 on the BOX layer. Although depicted as generally cylindrical, the bottom electrode 302 may alternatively comprise an open prism shape having a triangular, rectangular, square, pentagonal, hexagonal, heptagonal, octagonal, trapezoidal, or any other suitable geometry.

An upper portion of the bottom electrode 302 may be disposed adjacent to an underside of the membrane layer 342. In some examples, the upper portion of the bottom electrode 302 is positioned adjacent to an outer edge region of the membrane layer 342.

A first gap (or first distance or space) between the mirror post mount 301 and the bottom electrode 302 may be greater than a second gap (or second distance or space) between the bottom electrode 302 and the mirror stage mount 303.

The second gap may be greater than the first gap, or the first and second gaps may be substantially equal.

As shown, the bottom electrode 302 may overlap with the membrane layer 342, the tensile stress layer 343, and the mirror layer 345 in a vertical direction. This overlap between the bottom electrode 302 and the membrane layer 342 can facilitate electrostatic actuation of the device.

For example, the bottom electrode 302 may overlap with an outer edge region of the tensile stress layer 343 in the vertical direction. The bottom electrode 302 may also overlap with an outer edge region of the mirror layer 345 in the vertical direction and/or an outer edge region of the membrane layer 342 in the vertical direction. It will be appreciated that other overlapping configurations may be used, depending on the desired actuation characteristics.

FIG. 3B illustrates a top view of the mirror stage 340 coupled to the suspended frame 335 via flexures 353 and 354.

To enable actuation, the device includes the bottom electrode 302 positioned relative to the membrane layer 342 to form a parallel plate actuator. The bottom electrode 302 is coupled (e.g., electrically coupled) to the mirror stage mount 303 (left portion of the mirror stage mount 303 in this example) via the second structural blade 322₂ and the third structural blade 322₃. An overlap region between the membrane layer 342 (acting as a movable top electrode) and the bottom electrode 302 defines the active area of the actuator.

This actuator is configured to modify the shape of the mirror layer 345 (e.g., curvature of the mirror layer 345) via electrostatic force between the membrane layer 342 and the bottom electrode 302. When a potential difference is applied between the membrane layer 342 and the bottom electrode 302 (e.g., different voltages applied to the membrane layer 342 and the bottom electrode 302), an electrostatic force attracts the membrane layer 342 toward the bottom electrode 302 (e.g., in the negative Z-direction). This force counteracts the initial stress-induced curvature (e.g., initial upward-concave curvature). By modulating the voltages applied to the membrane layer 342 and the bottom electrode 302, the curvature of the mirror layer 345 can be continuously adjusted. For example, an initially concave mirror (e.g., an upward-concave curvature of the mirror layer, “U” shaped curvature of the mirror layer, bowl-shaped curvature) can be flattened or, if the initial stiffness and spacing permit, inverted into a downwardly concave curvature (e.g., “∩”-shaped or upside-down bowl curvature).

FIG. 3B illustrates an exemplary electrical routing path configured to bias the membrane layer 342 relative to the bottom electrode 302. To adjust the curvature of the mirror layer 345 (e.g., initial upward-concave curvature of the mirror layer 345), the first voltage V_{M} for the membrane layer 342 is transmitted through the first flexure 354 (located on the right side). Likewise, the second voltage V_{BE} for the bottom electrode 302 is transmitted through the second flexure 353 (located on the left side).

In this disclosure, the first voltage V_{M} supplied to the first flexure 354 and the second voltage V_{BE} supplied to the second flexure 353 are routed through mutually isolated conductive paths, thereby electrically insulating the first voltage V_{M} from the second voltage V_{BE}. As shown, isolation members (e.g., isolation members 364) facilitate the electrical isolation of these paths.

FIGS. 3B and 3C detail the electrical routing path for delivering the first voltage V_{M} to the membrane layer 342.

In this configuration, a metal trace 350 disposed on the suspended frame 335 carries the first voltage V_{M}. This trace 350 is coupled to the underlying silicon wafer via a contact 351 extending through a top oxide layer 355. The first voltage V_{M} propagates through the first flexure 354 to the mirror stage mount 303 (portion of the mirror stage mount 303 on the right side in this example). Within the mirror stage mount 303, the electrical signal (first voltage V_{M}) bridges a vertical isolation member 364 via a jumper configuration comprising contacts 351 and a second segment of the metal trace 350, thereby reaching an inner region of the mirror stage mount 303 disposed between the bottom electrode 302 and the isolation member 364.

From the inner region, a first vertical interconnect 362₁ (e.g., conductive vias or plugs such as polysilicon plugs) extends through the buried oxide (BOX) layer to transfer the first voltage V_{M} to the first structural blade 322₁ disposed between second structural blade 322₂ and third structural blade 322₃. The first structural blade 322₁ provides a conductive link to a second vertical interconnect 362₂. The second vertical interconnect 362₂ extends through the BOX layer to electrically couple the first structural blade 322₁ to the mirror post mount 301, the mirror post 341, and the membrane layer 342. Consequently, the first voltage V_{M} is effectively transmitted from the metal trace 350 to the membrane layer 342 via the first flexure 354 and the first structural blade 322₁.

FIGS. 3A and 3B illustrate the electrical routing path for the bottom electrode 302.

In this exemplary configuration, a second metal trace 350′ disposed on the suspended frame 335 carries the second voltage V_{BE} (e.g., ground voltage), which ultimately reaches the bottom electrode 302. This trace 350′ is electrically coupled to the underlying silicon wafer via a second contact 351′ extending through the top oxide layer 355. The second voltage V_{BE} is transferred via the second metal trace 350′ and the second contacts 351′ to the second flexure 353 (located on the left side), through which it propagates to the mirror stage mount 303 (portion of the mirror stage mount 303 on the left side in this example). To bypass the isolation members 364, the second voltage V_{BE} utilizes additional contacts 351′ and metal trace segments 350′ to reach first and second regions A, B of the mirror stage mount 303 (portions of the mirror stage mount 303 located on the left side). From these regions, vertical interconnects 362 (e.g., conductive vias or plugs such as polysilicon plugs) transfer the second voltage V_{BE} through the BOX layer to the second structural blade 322₂ and the third structural blade 322₃. The second structural blade 322₂ and the third structural blade 322₃ are then electrically coupled to the bottom electrode 302 via additional vertical interconnects 362. Furthermore, the second voltage V_{BE} may be distributed to tilting blades 320 via vertical interconnects 362 to facilitate rotation of the device about the X-axis.

As illustrated with dotted lines in FIGS. 3A and 3B, the second voltage V_{BE} (e.g., ground voltage) propagates via the second flexure 353 (located on the left side) to the second structural blade 322₂ and the third structural blade 322₃. The second voltage V_{BE} then propagates from the second structural blade 322₂ and the third structural blade 322₃ to the bottom electrode 302. These electrical connections may be provided by vertical interconnects 362 (e.g., conductive vias or plugs such as polysilicon plugs) that electrically couple the second flexure 353 to the second structural blade 322₂ and the third structural blade 322₃, and further electrically couple both the second structural blade 322₂ and the third structural blade 322₃ to the bottom electrode 302.

For example, a third vertical interconnect 362₃, disposed at least partially within a via or hole in the BOX layer, may electrically couple the second flexure 353 to the second structural blade 322₂, while a fourth vertical interconnect 362₄, disposed at least partially within a via or hole in the BOX layer, electrically couples the second flexure 353 to the third structural blade 322₃.

Further, at least one of fifth vertical interconnects 362₅, disposed at least partially within vias or holes in the BOX layer, may electrically couple the second structural blade 322₂ to the electrode 302, while at least one of sixth vertical interconnects 362₆, disposed at least partially within vias or holes in the BOX layer, may electrically couple the third structural blade 322₃ to the electrode 302.

Consequently, the second voltage V_{BE} (actuation voltage in this example) is effectively delivered to the bottom electrode 302 through the structural support provided by the second and third structural blades 322 from the metal trace 350′ via the second flexure 353.

The potential difference (voltage difference) established between the membrane layer 342 and the bottom electrode 302 generates an electrostatic force that pulls the membrane layer 342, and thus the mirror layer 345, in the negative Z-direction (e.g., downward). This actuation may be subject to a pull-in instability limit; if the voltage difference exceeds a critical threshold, the membrane layer 342 may destabilize and snap down onto the bottom electrode 302. This physical limitation defines the maximum range of motion and, consequently, the maximum achievable change in the radius of curvature for the mirror layer 345. For example, a mirror layer 345 with an initial upward-concave curvature with a radius of 12 mm may be electrostatically actuated to a substantially flat state. Alternatively, if the initial curvature (e.g., initial upward-concave curvature) is less pronounced (e.g., a 20 mm radius), the mirror layer 345 may be actuated past the flat point into an opposing shape, such as a downward-concave curvature with a radius of curvature of 20 mm.

### (c) Adjustable Curvature Mirror with Comb Finger Actuator

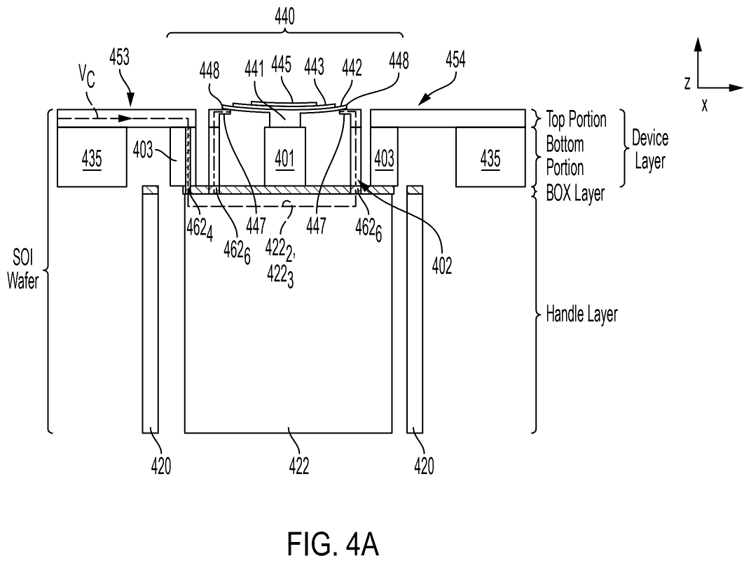

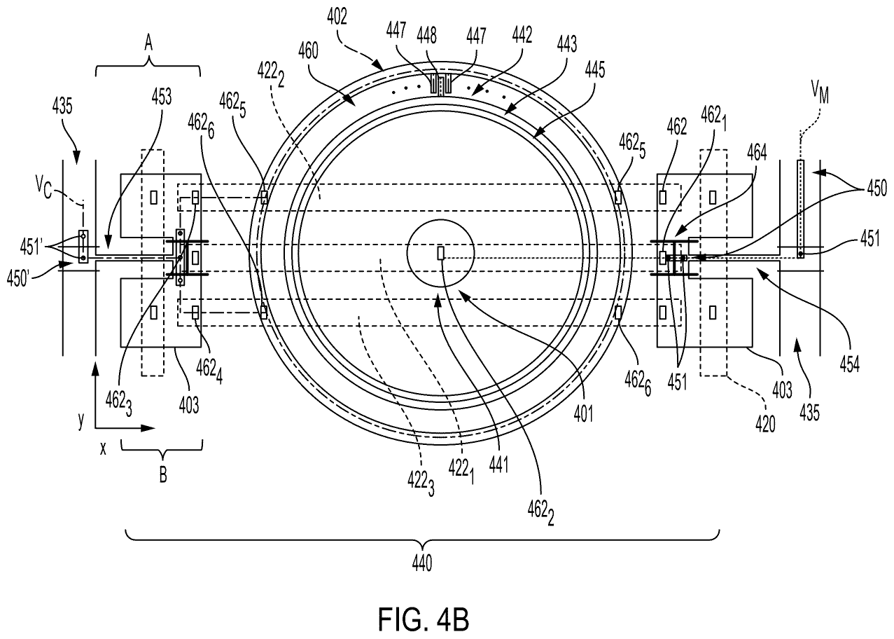

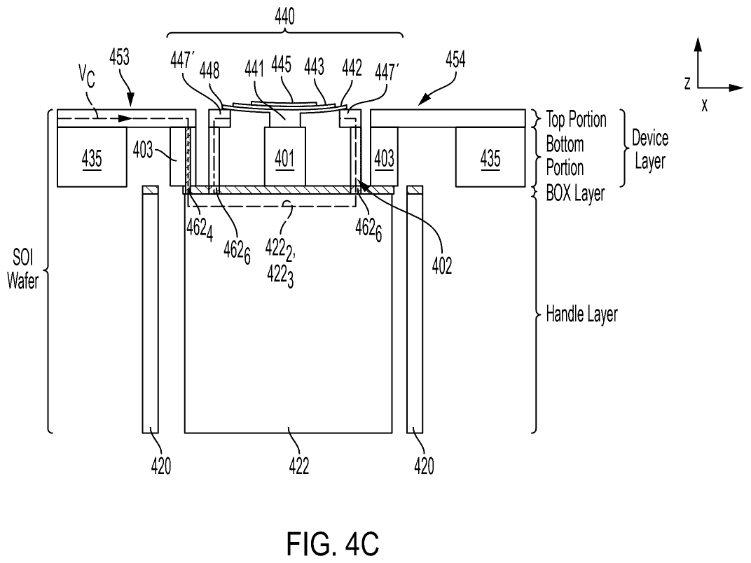

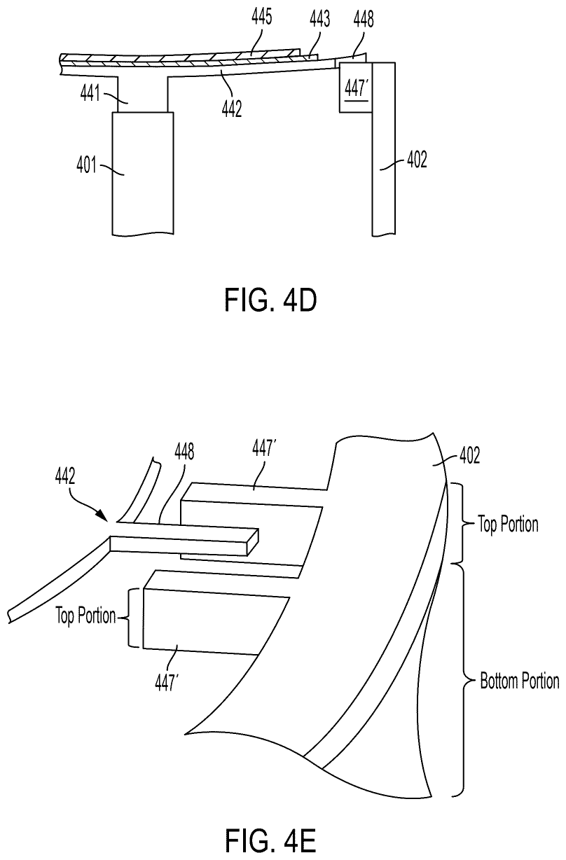

FIG. 4A illustrates a cross-sectional view of a mirror stage 440 coupled to a suspended frame 435 via flexures 453 and 454. As shown, the mirror stage 440 includes a membrane layer 442, a mirror layer 445, and a tensile stress layer 443 between the membrane layer 442 and the mirror layer 445. As described previously, in some implementations, the mirror stage 440 may include a tensile stress layer (e.g., tensile stress layer 243′ in FIG. 2B) on the upper surface of the mirror layer 445. In some implementations, the mirror stage 440 may include a compressive stress layer (e.g., compressive stress layer 244 in FIG. 2C) on the bottom side of the membrane layer 442. Any combination of a tensile stress layer between the mirror layer 445 and the membrane layer 442, a tensile stress layer on the upper surface of the mirror layer 445, and/or a compressive stress layer on the bottom side of the membrane layer 442 can be used to create an upward-concave curvature in the mirror layer 445. Also as described previously, for fine-tuning the curvature of the mirror layer 445 or to change the curvature of the mirror layer 445 to a downward-concave curvature (e.g., “∩” or upside-down bowl-shaped curvature), a tensile stress layer may be disposed on the bottom side of the membrane layer 442 and/or a compressive stress layer may be disposed on the top side of the membrane layer 442.

In contrast to the fixed-curvature examples (e.g., FIGS. 2A-2C), the example shown in FIG. 4A incorporates a comb finger actuation mechanism configured to dynamically adjust the curvature of the mirror layer 445 of the mirror stage 440 (e.g., upward-concave curvature of the mirror layer 445).

As described herein, one or more stress-inducing layers may be included to impart an initial curvature (e.g., a rest-state curvature). For example, the tensile stress layer 443 may be disposed between the membrane layer 442 and the mirror layer 445 to induce an upward-concave curvature (e.g., “U” shaped or bowl-shaped curvature). The tensile stress layer 443 may be disposed on top of the mirror layer 445, or both on top of the mirror layer 445 and between the membrane layer 442 and the mirror layer 445. Alternatively, or in combination, a compressive stress layer (e.g., similar to compressive stress layer 244 in FIG. 2C) may be disposed on the underside of the membrane layer 442.

The mirror layer 445 of FIG. 4A is disposed on the tensile stress layer 443, which in turn is disposed on the membrane layer 442. The tensile stress layer 443 induces an upward-concave curvature in the membrane layer 442 and the mirror layer 445. As shown, the membrane layer 442 is mechanically coupled to a mirror post mount 401 via a mirror post 441. The mirror post 441 may be formed form a device layer of the wafer (e.g., top portion of the device layer of the SOI wafer). The mirror post mount 401 may be formed from a device layer of the wafer (e.g., a bottom portion of the device layer of the SOI wafer), is mechanically and electrically coupled to a first structural blade 422₁ (shown in FIG. 4B), which is disposed between a second structural blade 422₂ and a third structural blade 422₃. In this example, the first structural blade 422₁ is coupled to a mirror stage mount 403 (on the right side) mechanically and electrically. As shown, in this example, the first structural blade 422₁, the second structural blade 422₂, and the third structural blade 422₃ are disposed between blades 420.

A comb mount 402 may also be formed from a device layer of a SOI wafer (e.g., top and/or bottom portions of the device layer). The comb mount 402 may define a hollow vertical structure, such as an open cylinder or tube. A lower end of the comb mount 402 may be disposed on a buried oxide (BOX) layer of the SOI wafer. In the illustrated configuration, the mirror post mount 401 is positioned within an interior region of the comb mount 402 on the BOX layer, while the mirror stage mount 403 is positioned externally, adjacent to sidewalls of the comb mount 402 on the BOX layer.

As shown, the comb mount 402 may include a plurality of comb fingers 447 that extends inward from the upper portion of the comb mount 402. As shown, the membrane layer 442 may include a plurality of comb fingers 448, complementary to the plurality of comb fingers 447, that extends outward.

A first gap (or first distance) between the mirror post mount 401 and the comb mount 402 may be greater than a second gap (or second distance) between the comb mount 402 and the mirror stage mount 403.

The second gap can be greater than the first gap, or the first and second gaps may be substantially equal.

FIG. 4B illustrates a top view of the mirror stage 440 coupled to the suspended frame 435 via flexures 453 and 454.

The comb mount 402, which may be formed from the device layer (e.g., comprising top and/or bottom portions of the device layer), is electrically coupled to the mirror stage mount 403 (left portion of the mirror stage of mount 403 in this example) via a second structural blade 422 and a third structural blade 422.

Similar to the bottom electrode 302 shown in FIG. 3A, as described previously, the comb mount 402 generally defines a hollow vertical structure or peripheral support structure, such as an open cylinder, tube, or prism. A lower end of the comb mount 402 is disposed on the BOX layer. The mirror post mount 401 is disposed within the interior of the comb mount 402, while the mirror stage mount 403 is positioned externally adjacent to the sidewalls of the comb mount 402.

In contrast to the bottom electrode 302 of FIG. 3A, the comb mount 402 includes the plurality of the comb fingers 447 extending inwardly from the upper portion of the comb mount 402. In this example, the plurality of comb fingers 447 of the comb mount 402 extends inwardly toward the membrane layer 442 (e.g., gaps between comb fingers 448) and/or the mirror post 441.

Correspondingly, the membrane layer 442 includes a plurality of complementary comb fingers 448 extending outwardly. In this example, the plurality of comb fingers 448 of the membrane layer 442 may extend in substantially lateral directions (e.g., toward gaps between comb fingers 447). As will be described later in this disclosure, due to the curvature of the mirror stage 440, the plurality of comb fingers 448 of the membrane layer 442 may extend based on the curvature of the mirror stage 440. The plurality of comb fingers 447 of the comb mount 402 extends in substantially lateral directions (e.g., toward the membrane layer 442).

Accordingly, the comb fingers 448 extending from the membrane layer 442 and the comb fingers 447 extending from the comb mount 402 are arranged in an interdigitated configuration to form a comb finger drive actuator. In this example, the interdigitated comb fingers (including the comb fingers 447 and the comb fingers 448) may surround (entire or at least portion of) the outer perimeter of the membrane layer 442 and the inner perimeter of the comb mount 402.

In this example, the structural vertical thickness (height) of the comb fingers 447 and 448 (extended from the membrane layer 442 and comb mount 402) is substantially the same as the vertical thickness (height) of the membrane layer 442. In other examples, the structural vertical thickness (height) of the comb fingers 447 extended from the comb mount 402 is greater than the vertical thickness (height) of the membrane layer 442.

The dimensions of the comb finger drive may vary based on design requirements. For example, the width of each comb fingers 447 and 448 (extended from the membrane layer 442 and comb mount 402) may be in a range of approximately 1.5 μm to 3.0 μm. The gap between adjacent comb fingers 447 and 448 may be in a range of approximately 2.0 μm to 3.0 μm.

Due to the initial curvature of the membrane layer 442 (e.g., upward-concave curvature having a radius between approximately 10 mm and 15 mm), a vertical offset may exist between the comb fingers 447 and the comb fingers 448. Specifically, the comb fingers 448 extending from the membrane layer 442 may be vertically displaced relative to the comb fingers 447 extending from the comb mount 402 (e.g., displaced by approximately 0.5 μm to 2 μm in the positive Z-direction).

When a potential difference is applied between the comb fingers 448 extended from the membrane layer 442 (first voltage) and the comb fingers 447 extended from the comb mount 402 (second voltage different from the first voltage), an electrostatic force is generated. In this example, the electrostatic force acts to reduce the vertical offset, displacing the movable comb fingers 448 extended from the membrane layer 442 in the negative Z-direction (e.g., downward).

This vertical displacement changes or modifies the shape of the membrane layer 442. Accordingly, the negative Z-direction displacement reduces the curvature of the mirror layer 445, thereby increasing the radius of curvature of the mirror layer 445 (e.g., flattening the mirror).

The electrostatic force counteracts the initial stress-induced curvature (for example, an upwardly concave or “U-shaped” or bowl-shaped curvature). By selectively modulating a first voltage applied to the comb fingers of the membrane layer 442 and a second voltage applied to the comb fingers of the comb mount 402, the curvature of the mirror layer 445 can be continuously adjusted. In this manner, an initially concave mirror layer 445 may be flattened or, if the initial stiffness and spacing allow, inverted into a downwardly concave curvature (e.g., “∩” shaped or upside-down bowl-shaped curvature).

FIG. 4B illustrates an exemplary electrical routing path configured to bias the comb fingers 427 extended from the comb mount 402 (e.g., stationary electrode elements) relative to the comb fingers 428 extended from the membrane layer 442 (e.g., movable electrode elements). To adjust the curvature of the mirror layer 445 (e.g., initial upward-concave curvature of the mirror layer 445), the first voltage V_{M} for the comb fingers 448 is transmitted through the first flexure 454 (located on the right side). Likewise, the second voltage V_{C} for the comb fingers 447 is transmitted through the second flexure 453 (located on the left side).

FIG. 4B details the electrical routing path for delivering the first voltage V_{M} to the membrane layer 442 and the comb fingers 448 extended from the membrane layer 442. In conjunction, FIG. 3C illustrates the path of the first voltage V_{M} from a different perspective to provide a more complete understanding of the routing.

In this example, the first voltage V_{M} in FIG. 4B is applied to the membrane 442 through an electrical routing path similar to that used for the first V_{M} in FIG. 3C.

In this configuration, a metal trace 450 disposed on the suspended frame 435 carries the first voltage V_{M}. This trace 450 is coupled to the underlying silicon wafer via a contact 451 extending through a top oxide layer 455 (e.g., top oxide layer 355 in FIG. 3C). The first voltage V_{M} propagates through the first flexure 454 to the mirror stage mount 403 (portion of the mirror stage mount 403 on the right side in this example). Within the mirror stage mount 403, the electrical signal (first voltage V_{M}) bridges a vertical isolation member 464 via a jumper configuration comprising contacts 451 and a second segment of the metal trace 450, thereby reaching an inner region of the mirror stage mount 403 disposed between the comb mount 402 and the isolation member 464.

From the inner region, a first vertical interconnect 462₁ (e.g., conductive vias or plugs such as polysilicon plugs) extends through the buried oxide (BOX) layer to transfer the first voltage V_{M} to the first structural blade 422₁ disposed between second structural blade 422₂ and third structural blade 422₃. The first structural blade 422₁ provides a conductive link to a second vertical interconnect 462₂. The second vertical interconnect 462₂ extends through the BOX layer to electrically couple the first structural blade 422₁ to the mirror post mount 401, the mirror post 441, and the membrane layer 442. Consequently, the first voltage V_{M} is effectively transmitted from the metal trace 450 to the membrane layer 442 and the comb fingers 448 extended from the membrane layer 442 via the first flexure 454 and the first structural blade 422₁.

FIGS. 4A and 4B illustrate the electrical routing path for the comb mount 402 and the comb fingers 447 extended from the comb mount 402. As shown, a second metal trace 450′ disposed on the suspended frame 435 carries the second voltage V_{C} (e.g., ground voltage), which ultimately reaches the comb fingers 447 extended from the comb mount 402. This trace 450′ is electrically coupled to the underlying silicon wafer via a second contact 451′ extending through the top oxide layer 455 (e.g., top oxide layer 355 in FIC. 3C). The second voltage V_{C} is transferred via the second metal trace 450′ and the second contacts 451′ to the second flexure 453 (located on the left side), through which it propagates to the mirror stage mount 403 (portion of the mirror stage mount 403 on the left side in this example). To bypass isolation members 464, the second voltage V_{C} utilizes additional contacts 451′ and metal trace segments 450′ to reach first and second regions A, B of the mirror stage mount 403 (portions of the mirror stage mount 403 located on the left side). From these regions, vertical interconnects 462 (e.g., conductive vias or plugs such as polysilicon plugs) transfer the second voltage V_{C} through the buried oxide (BOX) layer to the second structural blade 422₂ and the third structural blade 422₃. The second structural blade 422₂ and the third structural blade 422₃ are then electrically coupled to the comb mount 402 and the comb fingers 447 extended from the comb mount 402 via additional vertical interconnects 462. Furthermore, the second voltage V_{C} may be distributed to tilting blades 420 via vertical interconnects 462 to facilitate rotation of the device about the X-axis.

As illustrated with dotted lines in FIGS. 4A and 4B, the second voltage V_{C} (e.g., ground voltage) propagates via the second flexure 453 (located on the left side) to the second structural blade 422₂ and the third structural blade 422₃. The second voltage V_{C} then propagates from the second structural blade 422₂ and the third structural blade 422₃ to the comb mount 402 and the comb fingers 447 extended from the comb mount 402. These electrical connections may be provided by vertical interconnects 462 (e.g., conductive vias or plugs such as polysilicon plugs) that electrically couple the second flexure 453 to the second structural blade 422₂ and the third structural blade 422₃, and further electrically couple both the second structural blade 422₂ and the third structural blade 422₃ to the comb mount 402 and the comb fingers 447 extended from the comb mount 402.

For example, a third vertical interconnect 462₃, disposed at least partially within a via or hole in the buried oxide (BOX) layer, may electrically couple the second flexure 453 to the second structural blade 422₂, while a fourth vertical interconnect 462₄, disposed at least partially within a via or hole in the BOX layer, electrically couples the second flexure 453 to the third structural blade 422₃.

Further, at least one of fifth vertical interconnects 462₅, disposed at least partially within vias or holes in the BOX layer, may electrically couple the second structural blade 422₂ to the comb mount 402 and the comb fingers 447 extended from the comb mount 402, while at least one of sixth vertical interconnects 462₆, disposed at least partially within vias or holes in the BOX layer, may electrically couple the third structural blade 422₃ to the comb mount 402 and the comb fingers 447 extended from the comb mount 402.

Consequently, the second voltage V_{C} (actuation voltage in this example) is effectively delivered to the comb mount 402 and the comb fingers 447 extended from the comb mount 402 through the structural support provided by the second and third structural blades 422₂ and 422₃ from the metal trace 450′ via the flexure 453.

As the height difference between the comb fingers 447 and the comb fingers 448 decreases, the force that displaces the membrane layer 442 in the negative z-direction decreases, thereby limiting the potential negative z-displacement of the membrane layer 442. In this example, the comb fingers 448 attached to the membrane layer 442 may not be positioned lower than the comb fingers 447 attached to the comb mount 402. Therefore, this method may not change the direction of the radius of curvature to the negative z-direction. For example, a mirror layer with an upward-concave curvature with a radius 20 mm could be pulled less than halfway down, resulting in an upward-concave curvature with a radius of about 35 mm.

A thermal mismatch between materials may provide a static downward-convex curvature (e.g., downward-concave curvature, upside-down bowl shaped-curvature, “∩” shaped curvature) to the membrane layer 442. This can result from a compressive stress layer on the top side of the membrane layer 442 or a tensile stress layer on the bottom side of the membrane layer 442. In these cases, the comb fingers 448 attached to the membrane layer 442 will be lower than, or negatively displaced in the z-direction relative to, the comb fingers 447 attached to the comb mount 402. Since differing voltages on opposing comb fingers 447 and 448 create an attractive force, a voltage difference will pull the membrane layer 442 in the positive z-direction, causing the mirror layer 445 to change from a downward-convex shape to a less downward-convex shape, thereby increasing the radius of curvature; however, it may not change from a downward-convex curvature to an upward-concave curvature.

FIGS. 4C, 4D, and 4E illustrate a comb finger drive actuator including a plurality of comb fingers 447′ extending from the comb mount 402. The comb fingers 447′ can have a height (thickness in the vertical or z-direction) that corresponds to the height or thickness of a top portion of a device layer of a SOI wafer.

As shown in this example, the plurality of comb fingers 447′ extending from the comb mount 402 has a height (vertical thickness) corresponding to the height or thickness of a top portion of a device layer of the SOI wafer, while the comb fingers 448 extending from the membrane layer 442 have a height (vertical thickness) corresponding to the thickness or height of the membrane layer 442.

In this example, the vertical thickness (height) of comb fingers 447′ extended from the comb mount 402 is greater than the vertical thickness (height) of comb fingers 448 extended from the membrane layer 442. As illustrated, the comb fingers 448 extended from the membrane layer 442 are curved up as extended closer to the comb fingers 447′ coupled to the comb mount 401.

In this example, when the tops of the comb fingers 447′ and 448 are at the same z-displacement (i.e., when the mirror layer 445 is flat), there is still a net downward force applied to the comb fingers 447 attached to the membrane layer 442. This means, for example, that a mirror layer 445 having an upward-concave curvature having a radius of 20 mm could be driven to a downward-convex curvature having a radius of about 80 mm. However, the force when the mirror layer 445 is near this flat level is still significantly reduced compared to the force at its initial displacement, which limits how much the mirror can be further curved downward.

### (d) Adjustable Curvature Mirror with Parallel Plate Assisted Comb Actuator

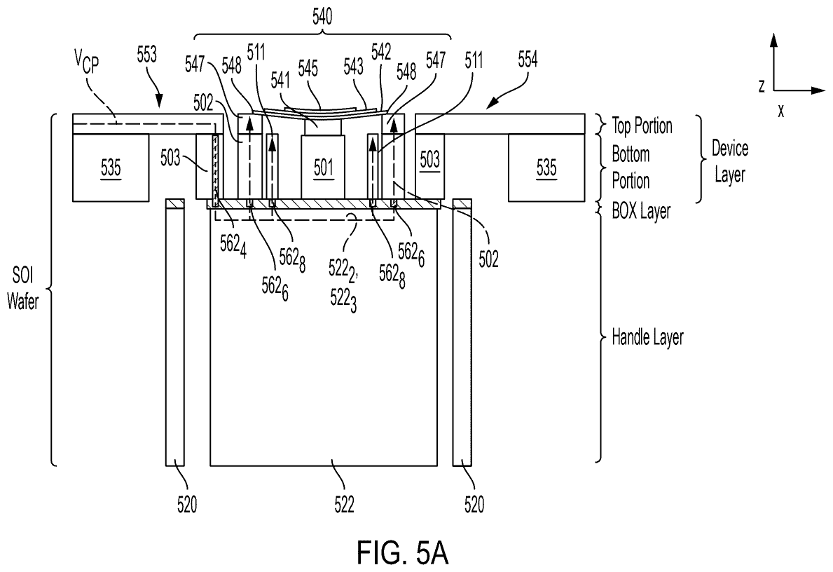

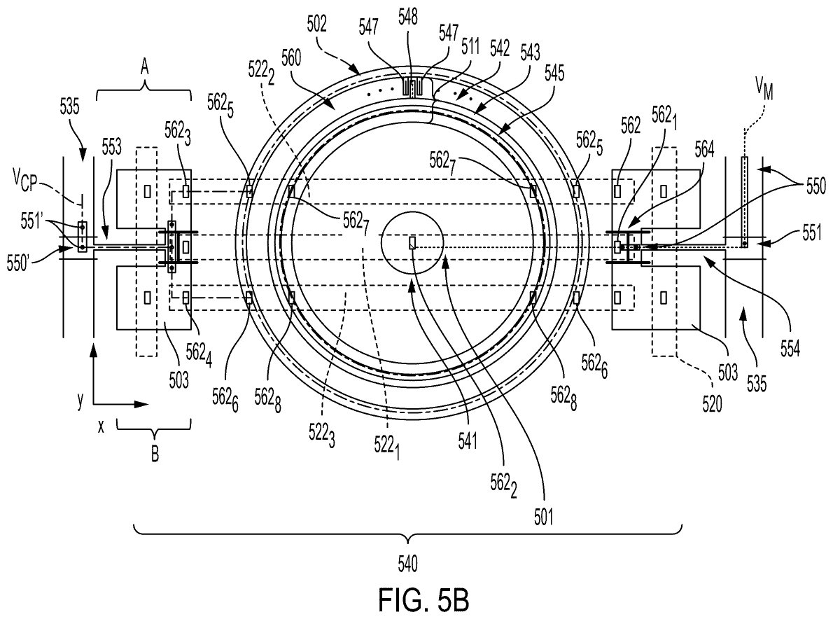

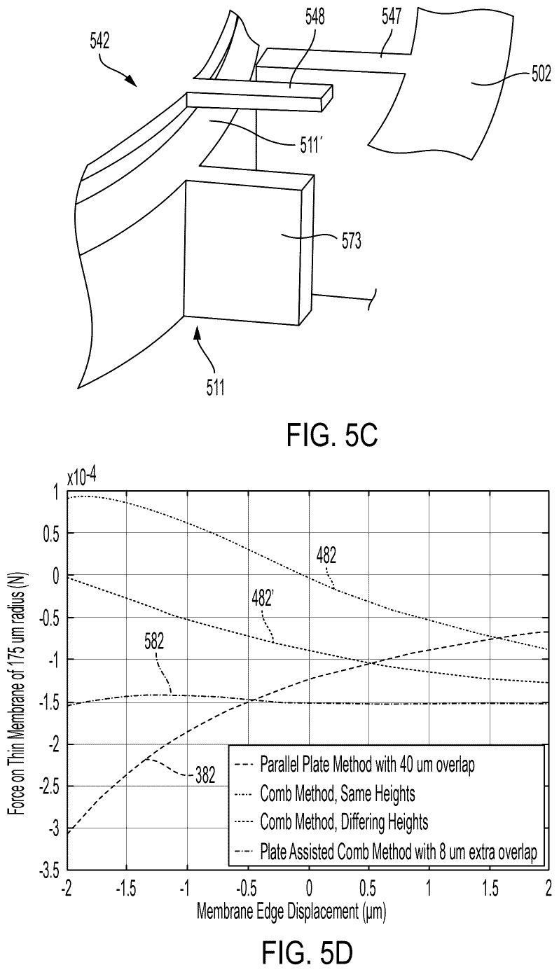

FIG. 5A illustrates a cross-sectional view of a mirror stage 540 coupled to a suspended frame 535 via flexures 553 and 554. As shown, the mirror stage 540 includes a membrane layer 542, a mirror layer 545, and a tensile stress layer 543 between the membrane layer 542 and the mirror layer 545. As described previously, in some implementations, the mirror stage 540 may include a tensile stress layer (e.g., tensile stress layer 243′ in FIG. 2B) on the upper surface of the mirror layer 545. In some implementations, the mirror stage 540 may include a compressive stress layer (e.g., compressive stress layer 244 in FIG. 2C) on the bottom side of the membrane layer 542. Any combination of a tensile stress layer between the mirror layer 545 and the membrane layer 542, a tensile stress layer on the upper surface of the mirror layer 545, and/or a compressive stress layer on the bottom side of the membrane layer 542 can be used to create an upward-concave curvature in the mirror layer 545. Also as described previously, for fine-tuning the curvature of the mirror layer or to change the curvature of the mirror layer to a downward-concave curvature (e.g., “∩” shaped or upside-down bowl-shaped curvature), a tensile stress layer may be disposed on the bottom side of the membrane layer 542 and/or a compressive stress layer may be disposed on the top side of the membrane layer 542.

A comb finger actuator similar to the comb finger actuators in FIGS. 4A-4B and 4C-4E, and a parallel plate actuator similar to the parallel plate actuator in FIGS. 3A-3C is shown. The actuation mechanism is configurable as a parallel-plate-assisted comb actuator to dynamically adjust the curvature of the mirror layer 545 of the mirror stage 540 (e.g., upward-concave curvature of the mirror layer 540).

As described herein, one or more stress-inducing layers may be included to impart an initial curvature (e.g., a rest-state curvature). For example, the tensile stress layer 543 may be disposed between the membrane layer 542 and the mirror layer 545 to induce an upward-concave) curvature. The tensile stress layer 543 may be disposed on top of the mirror layer 545, or both on top of the mirror layer 545 and between the membrane layer 542 and the mirror layer 545. Alternatively, or in combination, a compressive stress layer (e.g., similar to compressive stress layer 244 in FIG. 2C) may be disposed on the underside of the membrane layer 542.

In the example of FIG. 5A, the mirror layer 545 is disposed on the tensile stress layer 543, which in turn is disposed on the membrane layer 542. The tensile stress layer 543 induces an upward-concave curvature in the membrane layer 542 and the mirror layer 545. As shown, the membrane layer 542 is mechanically coupled to a mirror post mount 501 via a mirror post 541. The mirror post 541 may be formed form a device layer of the wafer (e.g., top portion of the device layer of the SOI wafer). The mirror post mount 501 may be formed from a device layer of the wafer (e.g., a bottom portion of the device layer of the SOI wafer), is mechanically and electrically coupled to a first structural blade 522₁ (shown in FIG. 5B), which is disposed between a second structural blade 522₂ and a third structural blade 522₃. In this example, the first structural blade 522₁ is coupled to a mirror stage mount 503 (on the right side) mechanically and electrically. As shown, in this example, the first structural blade 522₁, the second structural blade 522₂, and the third structural blade 522₃ are disposed between blades 520.

A comb mount 502 may also be formed from a device layer of a SOI wafer (e.g., top and/or bottom portions of the device layer portion). The comb mount 502 may define a hollow vertical structure, such as an open cylinder or tube. A lower end of the comb mount 502 may be disposed on a buried oxide (BOX) layer. In the illustrated configuration, the mirror post mount 501 is positioned within an interior region of the comb mount 502 on the BOX layer, while the mirror stage mount 503 is positioned externally, adjacent to sidewalls of the comb mount 502 on the BOX layer of the SOI wafer.

As shown, the comb mount 502 may include a plurality of comb fingers 547 that extends inward from the upper portion of the comb mount 502. As shown, the membrane layer 542 may include a plurality of comb fingers 548, complementary to the plurality of comb fingers 547, that extends outward.

Similar to the comb fingers 447 and the comb fingers 448 in FIGS. 4A and 4B, the comb fingers 547 extending from the comb mount 502 and the comb fingers 548 extending from the membrane layer 542 can have a height (vertical thickness) that is the same as the height of the membrane layer 542. Similar to comb fingers 447 and the comb fingers 448 in FIG. 4C-4E, the plurality of comb fingers 547 extending from the comb mount 502 can have a height (vertical thickness) corresponding to the height of a top portion of a device layer of the SOI wafer, while the comb fingers 548 extending from the membrane layer 542 have a height (vertical thickness) corresponding to the thickness of the membrane layer 542.

In some implementations, the plurality of comb fingers 547 extending from the comb mount 502 can have a height (vertical thickness) corresponding to the height of the device layer (including the top portion and the bottom portion) of the SOI wafer, while the comb fingers 548 extending from the membrane layer 542 have a height (vertical thickness) corresponding to the thickness of the membrane layer 542.

A parallel plate assistance electrode 511 may also be formed from a device layer of a SOI wafer (e.g., a bottom portion of the device layer of the SOI wafer). The parallel plate assistance electrode 511 may define a hollow vertical structure, such as an open cylinder or tube. A lower end of the plate assistance electrode 511 may be disposed on the buried oxide (BOX) layer. As illustrated, the mirror post mount 501 is positioned within an interior region of the parallel plate assistance electrode 511 on the BOX layer, while the comb mount 502 is positioned externally, adjacent to sidewalls of the parallel plate assistance electrode 511 on the BOX layer. Although depicted as generally cylindrical, the parallel plate assistance electrode 511 may alternatively comprise an open prism shape having a triangular, rectangular, square, pentagonal, hexagonal, heptagonal, octagonal, trapezoidal, or any other suitable geometry.

An upper portion of the parallel plate assistance electrode 511 may be disposed adjacent to an underside of the membrane layer 342.

As shown, the parallel plate assistance electrode 511 may overlap with at least one of the membrane layer 542, the tensile stress layer 543, and the mirror layer 545 in a vertical direction. This overlap between the parallel plate assistance electrode 511 and the membrane layer 542 can facilitate electrostatic actuation of the device. It will be appreciated that other overlapping configurations may be used, depending on the desired actuation characteristics.

In this example, the parallel plate assistance electrode 511 is electrically connected to the second structural blade 522₂ and the third structural blade 522₃. As a result, the parallel plate assistance electrode 511 and the comb fingers 547 attached to the comb mount 502 are biased at the same voltage. When the second voltage V_{CP} applied to the parallel plate assistance electrode 511 and the comb fingers 547 differs from the first voltage V_{M} applied to the membrane layer 542 and the comb fingers 548 attached to the membrane layer 542, the membrane layer 542 and the comb fingers 548 are driven in the negative z-direction, thereby reducing an upward-concave curvature, flattening the mirror, or producing a downward convex curvature (e.g., downward-concave, “∩”-shaped curvature, upside-down bowl-shaped curvature) of the mirror layer 545.

The electrostatic force counteracts the initial stress-induced curvature (for example, an upwardly concave, “U-shaped” curvature, or bowl shape curvature). By independently modulating a first voltage V_{M} applied to the comb fingers 548 of the membrane layer 542, a second voltage V_{CP} applied to both the comb fingers 547 of the comb mount 502 and the parallel-plate assistance electrode 511, the curvature of the mirror layer 545 can be continuously adjusted. In this manner, an initially concave mirror (e.g., upwardly concave, “U” shaped curvature, bowl shaped curvature) may be flattened or, if the stiffness and spacing permit, inverted into a downwardly concave (downward-concave curvature, “∩” shaped curvature, upside-down bowl shape curvature) configuration.

FIG. 5B illustrates an exemplary electrical routing path configured to bias the parallel plate assistance electrode 511 and the comb fingers 527 extended from the comb mount 502 (e.g., stationary electrode elements) relative to the membrane layer 542 and the comb fingers 528 extended from the membrane layer 542 (e.g., movable electrode elements). To adjust the curvature of the mirror layer 545 (e.g., initial upward-concave curvature of the mirror layer 545), the first voltage V_{M} for the comb fingers 548 and the membrane layer 542 is transmitted through the first flexure 554 (located on the right side). Likewise, the second voltage V_{CP} for the comb fingers 547 and the parallel plate assistance electrode 511 is transmitted through the second flexure 553 (located on the left side).

FIG. 5B details the electrical routing path for delivering the first voltage V_{M} to the membrane layer 542 and the comb fingers 548 extended from the membrane layer 542. In conjunction, FIG. 3C illustrates the path of the first voltage V_{M} from a different perspective to provide a more complete understanding of the routing.

In this example, the first voltage V_{M} in FIG. 5B is applied to the membrane 542 through an electrical routing path similar to that used for the first V_{M} in FIG. 3C.

A metal trace 550 can be disposed on the suspended frame 535 that carries the first voltage. This trace 550 is couplable to the underlying silicon wafer via a contact 551 extending through a top oxide layer 555 (e.g., top oxide layer 355 in FIC. 3C). The first voltage V_{M} propagates through the first flexure 554 to the mirror stage mount 503 (portion of the mirror stage mount 503 on the right side in this example). Within the mirror stage mount 503, the electrical signal (first voltage V_{M}) bridges a vertical isolation member 564 via a jumper configuration comprising contacts 551 and a second segment of the metal trace 550, thereby reaching an inner region of the mirror stage mount 503 disposed between the comb mount 502 and the isolation member 564.

From the inner region, a first vertical interconnect 562₁ (e.g., conductive vias or plugs such as polysilicon plugs) extends through the buried oxide (BOX) layer to transfer the first voltage V_{M} to the first structural blade 522₁ disposed between second structural blade 522₂ and third structural blade 522₃. The first structural blade 522₁ provides a conductive link to a second vertical interconnect 562₂. The second vertical interconnect 562₂ extends through the BOX layer to electrically couple the first structural blade 522₁ to the mirror post mount 501, the mirror post 541, and the membrane layer 542. Consequently, the first voltage V_{M} is effectively transmitted from the metal trace 550 to the membrane layer 542 and the comb fingers 548 extended from the membrane layer 542 via the first flexure 554 and the first structural blade 522₁.

FIGS. 5A and 5B illustrate the electrical routing path for the comb mount 502, the comb fingers 547 extended from the comb mount 502, and the parallel plate assistance electrode 511. A second metal trace 550′ disposed on the suspended frame 535 can be operable to carry the second voltage (e.g., ground voltage), which ultimately reaches the comb fingers 547 and the parallel plate assistance electrode 511. This trace 550′ is electrically coupled to the underlying silicon wafer via a second contact 551′ extending through the top oxide layer 555 (e.g., top oxide layer 355 in FIG. 3C). The second voltage V_{CP} is transferred via the second metal trace 550′ and the second contacts 551′ to the flexure 553 (located on the left side), through which it propagates to the mirror stage mount 503 (portion of the mirror stage mount 503 on the left side in this example). To bypass isolation members 564, the second voltage V_{CP} utilizes additional contacts 551′ and metal trace segments 550′ to reach first and second regions A, B of the mirror stage mount 503 (portions of the mirror stage mount 503 located on the left side). From these regions, vertical interconnects 562 (e.g., conductive vias or plugs such as polysilicon plugs) transfer the second voltage V_{CP} through the buried oxide (BOX) layer to the second structural blade 522₂ and the third structural blade 522₃. The second structural blade 522₂ and the third structural blade 522₃ are then electrically coupled to the comb mount 502, the comb fingers 547 extended from the comb mount 502, and the parallel plate assistance electrode 511 via additional vertical interconnects 562.

Furthermore, the second voltage V_{CP} may be distributed to tilting blades 520 via vertical interconnects 562 to facilitate rotation of the device about the X-axis.

As illustrated with dotted lines in FIGS. 5A and 5B, the second voltage V_{CP} (e.g., ground voltage) propagates via the second flexure 553 (located on the left side) to the second structural blade 522₂ and the third structural blade 522₃. The second voltage V_{CP} then propagates from the second structural blade 522₂ and the third structural blade 522₃ to the comb mount 502, the comb fingers 547 extended from the comb mount 502, and the parallel plate assistance electrode 511. These electrical connections may be provided by vertical interconnects 562 (e.g., conductive vias or plugs such as polysilicon plugs) that electrically couple the second flexure 553 to the second structural blade 522₂ and the third structural blade 522₃, and further electrically couple both the second structural blade 522₂ and the third structural blade 522₃ to the comb mount 502, the comb fingers 547 extended from the comb mount 502, and the parallel plate assistance electrode 511.

For example, a third vertical interconnect 562₃, disposed at least partially within a via or hole in the buried oxide (BOX) layer, may electrically couple the second flexure 553 to the second structural blade 522₂, while a fourth vertical interconnect 562₄, disposed at least partially within a via or hole in the BOX layer, electrically couples the flexure 553 to the third structural blade 522₃.

Further, at least one of fifth vertical interconnects 562₅, disposed at least partially within vias or holes in the BOX layer, may electrically couple the second structural blade 522₂ to the comb mount 502 and the comb fingers 547 extended from the comb mount 502, while at least one of sixth vertical interconnects 562₆, disposed at least partially within vias or holes in the BOX layer, may electrically couple the third structural blade 5223 to the comb mount 502 and the comb fingers 547 extended from the comb mount 502.

Further, at least one of seventh vertical interconnects 562₇, disposed at least partially within vias or holes in the BOX layer, may electrically couple the second structural blade 522₂ to the parallel plate assistance electrode 511, while at least one of eighth vertical interconnects 562₈, disposed at least partially within vias or holes in the BOX layer, may electrically couple the third structural blade 522₃ to the parallel plate assistance electrode 511.

Consequently, the second voltage V_{CP} (actuation voltage in this example) is effectively delivered to the comb mount 502, the comb fingers 547 extended from the comb mount 502, and the parallel plate assistance electrode 511 through the structural support provided by the second and third structural blades 522 from the metal trace 550′ via the second flexure 553.

FIG. 5C illustrates a perspective view of the comb fingers 547 and the comb fingers 548 in an interdigitated configuration.

The parallel plate assistance electrode 511 acts as bottom electrode (e.g., bottom electrode 302). The parallel plate assistance electrode 511 includes a first portion and a second portion. The first potion is a parallel plate assistance electrode main body 511′, which is disposed under the membrane layer 542. In this example, the parallel plate assistance electrode main body 511′ has as an open cylindrical shape or tube shape.

The second portion 511″ of the parallel plate assistance electrode 511 includes one or more protrusions extending outward from the periphery of the parallel plate assistance electrode main body 511′ that are disposed under the comb fingers 547 extended from (e.g., coupled to) the membrane layer 542. The parallel plate assistance main body 511′ may have a width between 5 μm and 20 μm.

In this example, the comb fingers 547 (extended from or coupled to the comb mount 502) include the top portion and bottom portion of the device layer. In other words, the height of the comb fingers 547 (vertical thickness) has the same height as the device layer (vertical thickness). The etching of the comb finger gaps up to the BOX layer of SOI wafer is the same or similar step that creates the gaps between plate assistance 511 and the bottom portion of the comb mount 502 and creates the protrusions 511″ out of bottom portion of the device layer.

In this example, the comb fingers 547 coupled to the comb mount 502 extend farther in the negative z-direction (e.g., downward) than in the example of FIGS. 4A and 4B, such that an applied voltage difference continues to generate a downward electrostatic force even when the top surfaces of the comb fingers 547 are level. As the membrane layer 542 and the comb fingers 548 coupled to the membrane layer 542 move in the negative z-direction, the gap of the parallel-plate assistance electrode 511 can decrease and thereby produce an increasing downward electrostatic force. Due to the comb finger actuation, the area of the parallel plate assistance electrode 511 can be smaller than the bottom electrode 302 of FIG. 3A and destabilization of the membrane layer 542 can be avoided. These combined effects can allow the mirror layer 545 to change the radius of curvature to an equal amount in the opposite direction. This mirror can change from an upward-concave curvature “U” with a radius of 12 mm to a downward-concave curvature (“∩” shaped) with a radius of 12 mm, which far exceeds the change in the mirrors using the previous methods of electrostatic actuation.

Because the comb fingers 547 coupled to the comb mount 502 extend farther in the negative z-direction (downward) than in the example of FIGS. 4A and 4B, the applied voltage difference continues to generate a downward force even when the top surfaces of all of the fingers 547 and 548 are level. As the membrane layer 542 and the comb fingers 548 coupled to the membrane layer 542 move in the negative z-direction, the parallel-plate gap of the plate assistance electrode 511 produces an increasing downward electrostatic force. This comb actuation allows the plate assistance electrode 511 to have a smaller area than the bottom electrode 302 of FIG. 3A, while avoiding destabilization (pull-in) of the membrane layer 542. Together, these effects enable the mirror layer 545 to change its radius of curvature by an equal magnitude in opposite directions, for example from an upward radius of curvature of 12 mm to a downward radius of curvature of 12 mm, which greatly exceeds the curvature change achievable with previous electrostatic actuation approaches.

FIG. 5D presents a plot of all three methods, including two versions of the comb finger method, showing force on the membrane layer (membrane layer 342, membrane layer 442, membrane layer 542) as a function of the z displacement of its outer edge. The system is simplified by assuming that the parallel plate portion and all portions of the comb fingers have the same z deflection, i.e. the slope at the edge of the membrane is neglected. The comb finger length in both comb finger methods and the plate assisted method is 25 μm long, 2 μm tall, and with a 3 μm gap. The membrane layer is 2μm tall. The absolute value of the parallel plate force 382 increases drastically as the membrane layer height decreases, which leads to destabilization at high applied voltages, thus limiting possible negative z deflection. The absolute value of the comb finger force 482 decreases and the force even changes direction as the membrane layer height decreases, which limits possible negative z deflection. When the comb fingers have different heights as in FIG. 4C, the force 482′ still decreases but is still negative at 0 displacement, i.e when the mirror is flat. This enables it to have a downward convex curvature. The plate assisted comb finger actuation provides a relatively consistent downward force 582, which allows for effective actuation without destabilization, resulting in a greater amount of change from starting as an upward concave mirror to a downward convex mirror.

### II. Methods of Manufacture

This disclosure describes methods for fabricating a Micro-Electro-Mechanical Systems (MEMS) array. In some implementations, the fabricating method comprises: forming etched regions on a top side of a silicon-on-insulator (SOI) wafer; forming partially etched regions on a top side of a second silicon-on-insulator (SOI) wafer; bonding the two wafers together; removing the bottom side and a buried oxide layer of the second silicon-on-insulator (SOI) wafer; forming a layer of dielectric material on a first side of a newly created substrate; forming, on the first side of the substrate, vertical isolation trenches containing dielectric material; patterning a masking layer on a second side of the substrate that is opposite to the first side of the substrate; removing a dielectric layer in certain regions on the first side of the substrate; depositing a compressive or tensile layer on the substrate in these regions; forming vias on the first side of the substrate; metallizing the first side of the substrate; depositing a second metal layer on the first side of the substrate to form a reflective surface; deeply etching the second side of the substrate to form narrow blades; bonding a base wafer to the second side of the substrate after forming the narrow blades; and forming second trenches on the first side of the substrate to define and release the structures and to provide electrical isolation. A lid can be placed on the top of the first side of the substrate, providing a hermetic seal. Additionally, the dielectric material can be silicon dioxide. The methods can include one or more of forming a passivation dielectric layer on the first side of the substrate after metallizing the first side of the substrate and attaching a lid wafer to the first side of the substrate. The lid wafer can also be comprised of glass.

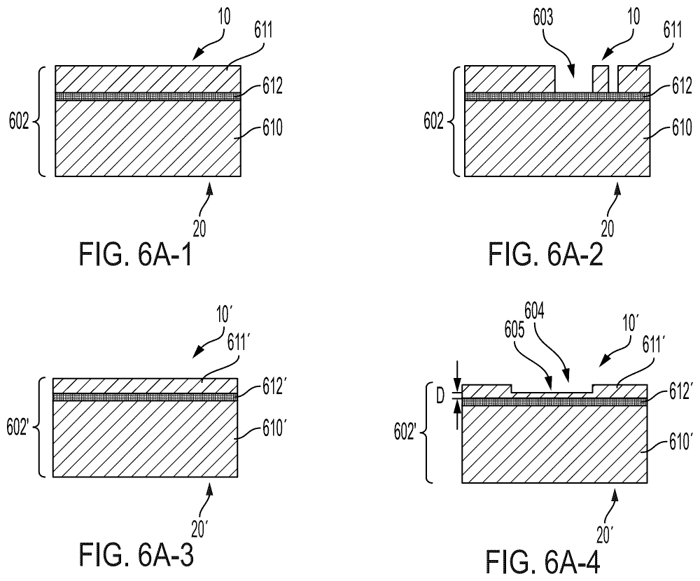

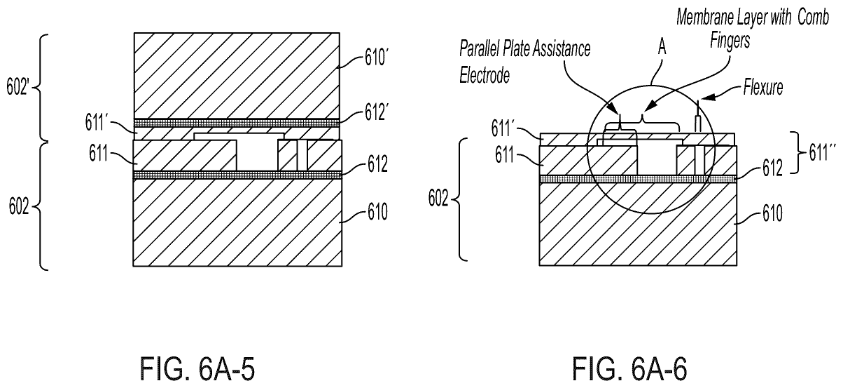

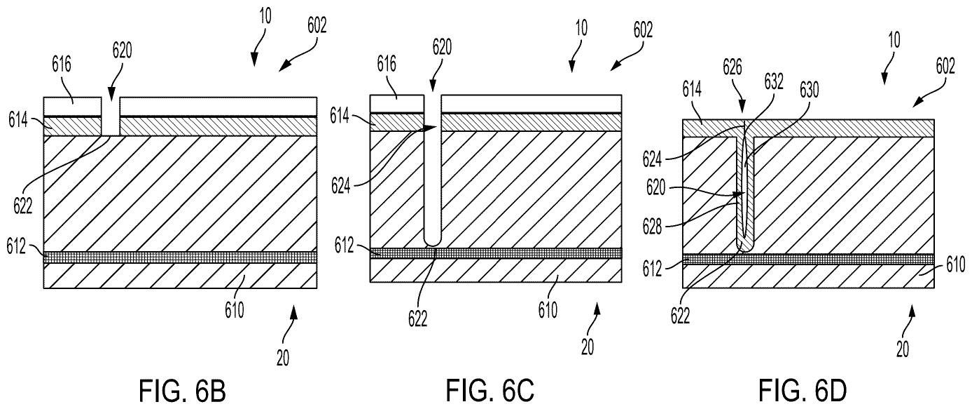

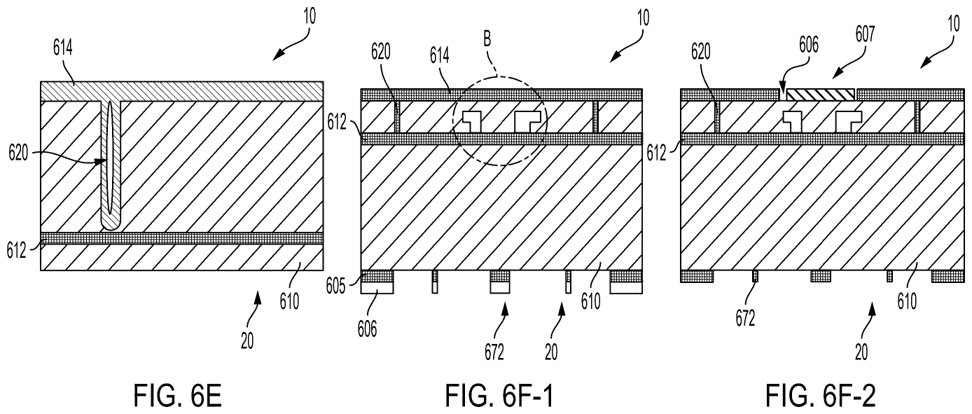

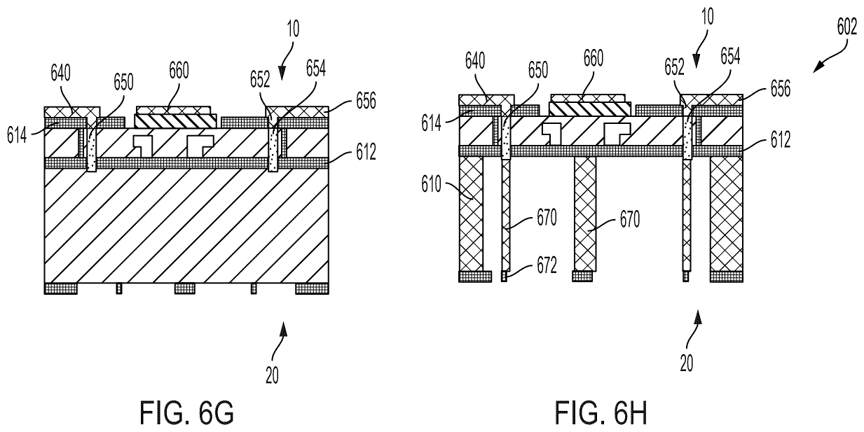

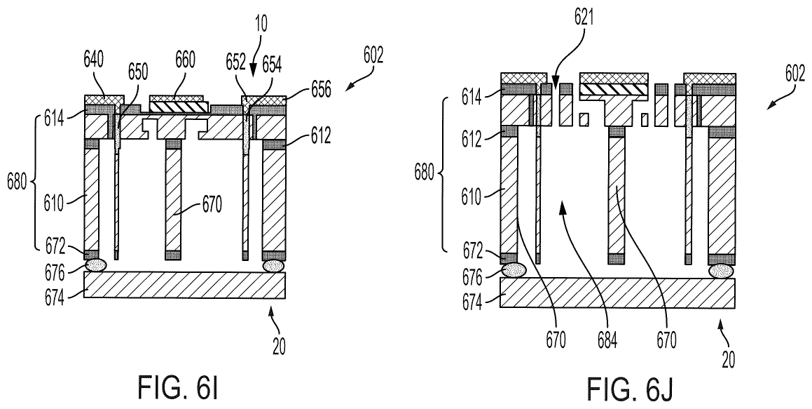

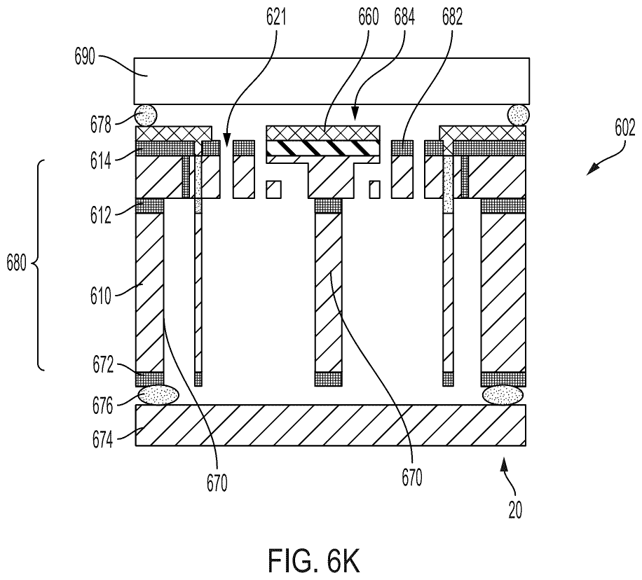

As shown, the method of fabricating a Micro-Electro-Mechanical Systems (MEMS) array involves the use of two device wafers (two SOI wafers in this example), and the corresponding method is described with reference to FIGS. 6A-6K.

FIG. 6A-1 illustrates, in one non-limiting example, a cross-section view of a first silicon-on-insulator (SOI) wafer 602. The first SOI wafer 602 may have a thickness between about 300 μm and 600 μm. The first SOI wafer 602 has a top side 10 (also referred to as a device side or simply a top) and a backside or a bottom side 20. The first SOI wafer 602 includes a device layer 611, a handle layer 610, and a buried oxide (BOX) layer 612 disposed between the device layer 611 and the handle layer 610.

Each layer within a MEMS actuator (for example, the MEMS actuators shown in FIG. 3A, FIG. 4A, and FIG. 5A) formed from the first SOI wafer 602 has a layer top surface oriented toward the top side 10 and a bottom surface oriented toward the bottom side 20. The BOX layer 612 may have a thickness between about 0.5 μm and 1 μm. The BOX layer 612 may be located at a depth of about 10 μm to 50 μm beneath the top side 10.

FIG. 6A-2 illustrates patterning and etching regions 603 into the top side 10 of the first SOI wafer 602. The regions 603 provide space between a mirror post mount (for example, mirror post mount 501) and a plate assistance electrode 511. The regions 603 may define the mirror post mount (for example, mirror post mount 501) and an inner radius of the parallel plate assistance electrode 511.

FIG. 6A-3 illustrates a second silicon-on-insulator (SOI) wafer 602′. The second SOI wafer 602′ may have a thickness between about 300 μm and 600 μm. The second SOI wafer 602′ has a top side 10′ (also referred to as a device side or simply a top) and a backside or a bottom side 20′. The second SOI wafer 602′ includes a device layer 611′, a handle layer 610′, and a buried oxide (BOX) layer 612′ disposed between the device layer 611′ and the handle layer 610′. The BOX layer 612′ may have a thickness between about 0.5 μm and 1 μm. The BOX layer 612′ may be located at a depth of about 5 μm to 10 μm beneath the top side 10′.

FIG. 6A-4 illustrates patterning and partially etching a region 604, leaving a thin silicon region 605. A possible thickness D of the region 605 could be about 2 μm. This thin silicon region 605 will eventually become a membrane layer (for example, a membrane layer 542) and comb fingers (for example, comb fingers 548 attached to the membrane layer 542). In FIG. 6A-4, a compressive or tensile layer could be deposited and etched to obtain regions of the layer on the silicon region 605. After the silicon region 605 is etched, the compressive or tensile layer can be deposited. Alternatively, the wafer can undergo thermal oxidation to produce a thin layer of silicon oxide everywhere on the surface. Using a resist to cover portions of the compressive or tensile layer inside the silicon region 605, the remaining layer can be etched. A thick resist can be used given the topology created by the region 605.

FIG. 6A-5 illustrates fusion bonding the second SOI wafer 602′ to the first SOI wafer 602. As shown, a top surface of the device layer 611′ of the second SOI wafer 602′ is fused to a top surface of the device layer 611 of the first SOI wafer 602.

FIG. 6A-6 illustrates the etching or removal of the handle layer 610′ of the second SOI wafer 602′ and of the buried oxide (BOX) layer 612′ of the second SOI wafer 602′. As shown, due to the fusion bonding process, the device layer 611 of the first SOI wafer 602 and the device layer 611′ of the second SOI wafer 602′ become one device layer 611″ of the first SOI wafer 602. In this disclosure, after the fusion bonding process, the device layer 611′ of the second SOI wafer 602′ is referred to as a top portion of the device layer 611″ of the first SOI wafer 602, and the device layer 611 of the first SOI wafer 602 is referred to as a bottom portion of the device layer 611″ of the first SOI wafer 602.

The circle A highlights at least two features. One of the features is a membrane layer (configured with comb fingers) with parallel plate assistance electrode that resembles an upside-down L rotated 90° to the right. The other feature is a cavity that allows for a flexure (e.g., spring). These features are not next to each other in a given design but are exemplary in this figure, as they show types of features that can exist in the design.

Referring to FIG. 6B, the first SOI wafer 602 is provided with a masking layer 614. The masking layer 614 may include one or more silicon dioxide layers (for example, an oxide layer). The first SOI wafer 602 can have arbitrary doping, resistivity, and crystal orientation, as the process relies solely on reactive ion etching to carve and form the structures. The masking layer 614 serves the function of protecting an upper surface of the first SOI wafer 602 during an isolation trench etching process. This masking layer 614 can be formed using any of a number of techniques, including thermal oxidation of silicon or chemical vapor deposition (CVD). A thickness of the masking layer 614 may be between about 0.5 μm and 1.0 μm. A photoresist layer 616 is then spun onto the silicon wafer 602 and exposed and developed using standard photolithography techniques to define an isolation trench pattern for an isolation trench 620. Reactive ion etching may be used to transfer the photoresist pattern to the masking layer 614, exposing the top surface of the first SOI wafer 602 (that is, a bottom 622 of the isolation trench 620). For example, a silicon dioxide mask can be etched using a Freon gas mixture (for example, CHF₃, CF₄). High etch rates for silicon dioxide etching can be achieved using a high-density plasma reactor, such as an inductively coupled plasma (ICP) chamber. These ICP chambers use a high-power RF source to sustain a high-density plasma and a low-power RF bias on the wafer to achieve high etch rates at low ion energies. For example, oxide etch rates of about 200 nm/min can be achieved, with selectivities to photoresist greater than about 1:1.

As illustrated in FIG. 6C, the isolation trench 620 is formed in the silicon wafer 602 by deep reactive ion etching of silicon using high etch-rate and high-selectivity etching. The trench is commonly etched in a high-density plasma using a sulfur hexafluoride (SF₆) gas mixture, as described in U.S. Pat. No. 5,501,893. Preferably, the etching is controlled so that an isolation trench 620 profile is reentrant, or tapered, with a top 624 of the isolation trench 620 being narrower than the bottom 622 of the isolation trench 620. Tapering of the isolation trench 620 ensures that good electrical isolation is achieved in subsequent processing. Profile tapering can be achieved in reactive ion etching by tuning a degree of passivation or by varying parameters (e.g., power, gas flows, pressure) of a discharge during the etching process. Because the isolation trench 620 is filled with a dielectric material, an opening at the top 624 of the isolation trench 620 is typically less than about 2 μm in width. A depth of the isolation trench 620 is typically in a range of about 10 μm to 50 μm. In some examples, the isolation trench 620 etch stops at the buried oxide layer 612. A common procedure for etching the isolation trench 620 is to alternate etch steps (SF₆ and argon mixture) with passivation steps (Freon with argon) in an ICP plasma to achieve etch rates in excess of about 2 μm/min at high selectivity to photoresist (>50:1) and oxide (>100:1). The power and a time of etch cycles are increased as the trench deepens to achieve the tapered profile. Although the trench geometry is preferably reentrant, arbitrary trench profiles can be accommodated with adjustments in microstructure processing. Good isolation results can be achieved with any of a number of known trench etch chemistries. After the silicon trench is etched, the photoresist layer 616 is removed with a suitable process (for example, a wet chemistry technique or a dry ashing technique).

Referring to FIG. 6D, the isolation trench 620 is then filled with an insulating dielectric material (for example, silicon dioxide). The filling procedure results in a mostly solid isolation segment in the isolation trench 620 and serves to deposit a layer of dielectric material on the top side 10 (top surface) of the first SOI wafer 602 and dielectric layers on a sidewall 628 and the bottom 622 of the isolation trench 620. A thickness of a deposited layer can be greater than about 1 μm. This fill can be accomplished with CVD techniques or, preferably, with oxidation of silicon at high temperatures. In thermal oxidation, the wafer is exposed to an oxygen-rich environment at temperatures from about 900° C. to 1150° C. This oxidation process consumes silicon surfaces to form silicon dioxide. A resulting volumetric expansion from this process causes the sidewalls of the trenches to encroach upon each other, eventually closing the trench opening. In a CVD fill, some dielectric is deposited on the walls, but filling also occurs from deposition on the bottom of the trench. CVD dielectric fill of trenches has been demonstrated with TEOS or silane mixtures in plasma-enhanced CVD chambers and low-pressure CVD furnace tubes. Another option is to coat the sides of the isolation trench 620 with silicon oxide and fill the isolation trench 620 with another material such as polysilicon or a material similar to polysilicon.

During the isolation trench 620 filling process, it is common for most isolation trench profiles to be incompletely filled, causing an interface 632 and a void 630 to be formed in the isolation trench 620. A local concentration of stress in the void 630 can cause electrical and mechanical malfunction in some devices but is generally unimportant for micromechanical devices due to an enclosed geometry of the isolation trench 620. The interface 632 and the void 630 can be eliminated by shaping the isolation trench 620 to be wider at an isolation trench opening located at the top 624 of the isolation trench 620 than at the bottom 622 of the isolation trench 620. However, good electrical isolation would then require additional tapering of a microstructure trench etch in later steps. Another artifact of the isolation trench filling process is an indentation 626 that is created in a surface of the masking layer 614 centered over the isolation trench 620. This indentation 626 is unavoidable in most trench filling processes and can be as deep as about 0.5 μm, depending on a thickness of a deposition. To remove the indentation 626, the surface is planarized to form a flat, or substantially flat, surface, as illustrated in FIG. 6E, for subsequent lithographic and deposition steps. The planarization is performed either by chemical-mechanical polishing (CMP) or by depositing a viscous material, which can be a photoresist, a spin-on glass, or a polyimide, and flowing the material to fill the indentation 626 to a smooth finish. During an etchback of the viscous material, which is a second step of planarization, the surface is etched uniformly, including the filled indentation. Therefore, by removing part of a surface oxide layer, the indentation 626 is removed to create a uniform-thickness layer. For example, if the masking layer 614 is originally about 2 μm in thickness, then planarization to remove the indentation 626 leaves the masking layer 614 having a final thickness of less than about 1 μm. The top side 10 (for example, an upper surface) of the first SOI wafer 602 is free from imperfection and is ready for further lithography and deposition.

FIG. 6F-1 shows the first SOI wafer 602 with the masking layer 614 and the isolation trenches 620. After the isolation trenches 620 are fabricated, standard front-to-back alignment is used to lithographically pattern the masking layer for blades on the bottom side 20 (backside) of the silicon wafer 602. The backside of the wafer is deposited with a layer 605, which may be a layer comprised of a combination of thermally grown silicon oxide and oxide deposited by CVD. The masking layer 605 may also be comprised of a metal layer such as aluminum. A resist 606 can be spun on an entire bottom side 20. As shown, a blade pattern 672 is exposed in the resist 606 and etched into the masking layer 605.

The lithography pattern is transferred into the masking layer 605 by reactive ion etching, yet the silicon blade etching is not completed until later in the process. Without the blades etched, the wafer is more easily processed through the remaining device layers. The backside of the blade pattern 672 is typically aligned top-side to the isolation trenches 620 to within several microns.

The circle B highlights one of the features shown in the circle A in FIGS. 6A-6, along with the same feature mirrored in an opposite direction. This results in two upside-down L features mirroring each other.

FIG. 6F-2 illustrates the patterning and removal of the masking layer 614 in certain regions 606. A tensile or compressive layer 607 can be placed in the region 606, through deposition and patterning of the tensile or compressive layer.

Metallization on the top side 10 of the silicon wafer 602 then proceeds as illustrated in FIG. 6G. In order to make contact to the underlying first SOI wafer 602, vias 652 are patterned and etched into the masking layer 614 using standard lithography and reactive ion etching. In some areas, the vias 652 may be etched through the buried oxide layer 612 and filled with polysilicon to produce polysilicon vias 650 and 654. After the vias 652 are etched, metallization is deposited to form a metal layer 640 and patterned to form a metal interconnect 656. For example, the metal can be aluminum and can be patterned using wet etching techniques. In mirror arrays with high interconnect densities, it is advantageous to pattern the metal using dry etching to achieve finer linewidths. The metal layer 640 is used to provide bond pads and interconnects, which connect electrical signals from control circuitry to each mirror to control mirror actuation, which includes both rotating a stage that the mirror is on and curving the mirror.

Deposition of a second metal layer (a mirror layer 660) provides a reflective mirror surface. This metal is tuned to provide high mirror reflectivity at optical wavelengths of interest and is typically deposited by evaporation and patterned using lift-off techniques to allow a broader choice of metallization techniques. For example, aluminum may be used. However, additional metal stacks such as Cr/Pt/Au may be used to increase reflectivity in wavelength bands common to fiber optics.

In order to rely on the compressive or tensile layer to produce a concave-upward curvature, the mirror metal thickness should be as thin as possible for acceptable reflectivity, and it may need to be further annealed to have minimal effect. Alternatively, the metal thickness and annealing could be chosen so that the mirror metal provides the desired concave-upward curvature. In this case, the additional compressive or tensile layer will be unnecessary.

As shown in FIG. 6H, backside silicon etching transfers the blade pattern 672 into the first SOI wafer 602 substrate to obtain blades 670. The etching is performed using deep silicon etching at high selectivity to oxide using the techniques disclosed in U.S. Pat. No. 5,501,893. The deep silicon etching achieves near-vertical profiles in the blades 670, which can be about 5 μm to 20 μm wide and in excess of about 300 μm deep. The etch stops on the buried oxide layer 612 to provide a uniform depth across the wafer while not punching through the top side 10 surface of the first SOI wafer 602. All blades 670 can be etched simultaneously across a mirror element and across a mirror array. The buried oxide layer 612 may be etched at this time.

Referring to FIG. 6I, because the first SOI wafer 602 (also referred to as a device wafer 680) is now prepared for microstructure release, the device wafer 680 becomes more susceptible to yield loss due to handling shock or air currents. In order to facilitate handling and aid in hermetically sealing a mirror array, a silicon wafer 674 is bonded to the device wafer 680 to protect the blades 670 after release. The bonding can be accomplished through the use of a bonding element 676, such as a frit glass material bonding element, that is heated to its flow temperature and then cooled. In this manner, a 400° C. bonding process using the bonding elements 676, such as frit glass material bonding elements, produces a hermetic seal to surround an entire mirror array. A separation (for example, a gap) between the device wafer 680 and the silicon wafer 674 using the bonding elements 676, such as frit glass material bonding elements, allows the blades 670 to swing through high rotation angles without impedance. Typically, a standoff required is greater than about 25 μm.

In FIG. 6J, the top-side processing is completed. First, a passivation dielectric layer (not shown) may be applied to protect the metallization during subsequent processing. The passivation dielectric layer is removed in a region of bonding pads and from an actuator region. At this step, a mirror structure including a frame, a mirror, and supports are defined using multiple etches that define trenches 621 separating structural elements. The etches are self-aligned and proceed through various metal, dielectric, and first SOI wafers 602. The various structures are now released.

To completely seal the mirrors from an outside environment, a lid wafer 690 is bonded to the device wafer 680, preferably through a bonding element 678 (for example, a frit glass seal), as shown in FIG. 6K. The lid wafer 690 is typically made of glass, which allows incoming light to be transmitted with low loss into a mirror cavity 684, reflect off an upper surface of the mirror layer 660, and then transmit out of the mirror cavity 684.

Although these teachings have been described with respect to various examples, it should be appreciated that these teachings are also capable of a wide variety of further and other examples within a spirit and scope of these teachings. Thus, although an overview of the subject matter has been described with reference to specific examples, various modifications and changes may be made to these examples without departing from a broader scope of the present disclosure. It will also be obvious to those skilled in the art that the examples are provided by way of example only. Numerous variations, changes, and substitutions will occur to those skilled in the art without departing from the scope of the disclosure. It should also be understood that various alternatives may be employed in practicing the disclosed innovation. It is intended that any claims presented at any time in this application, or in a subsequent application, define the scope of the invention and that methods and structures within the scope of any claims and their equivalents are covered thereby.

What is claimed is:

1. An adjustable-curvature micro-electro-mechanical systems (MEMS) mirror device comprising:
a frame;
a mirror stage coupled to the frame via a plurality of flexures including a first flexure and a second flexure, the mirror stage comprising a membrane layer and a mirror layer disposed on the membrane layer;
a mirror post mount and a mirror post extending from the mirror post mount, the mirror post mount and the mirror post supporting the mirror stage;
a bottom electrode having an upper portion disposed adjacent to an underside of the membrane layer;
wherein the first flexure is electrically coupled to the membrane layer;
wherein the second flexure is electrically coupled to the bottom electrode; and
wherein a first voltage supplied to the first flexure and a second voltage supplied to the second flexure are routed through mutually isolated conductive paths such that the first voltage is insulated from the second voltage.

2. The device of claim 1, wherein the bottom electrode is formed from a device layer of a silicon-on-insulator wafer and defines a hollow vertical structure surrounding the mirror post mount with a lower end disposed on a buried oxide layer of the silicon-on-insulator wafer.

3. The device of claim 1, wherein the upper portion of the bottom electrode is disposed adjacent to an outer edge region of the membrane layer such that the bottom electrode overlaps the membrane layer in a vertical direction to form a parallel-plate actuator.

4. The device of claim 1, wherein a voltage difference between the membrane layer and the bottom electrode generates an electrostatic force that draws the membrane layer toward the bottom electrode to reduce an initial upward-concave curvature of the mirror layer and/or to change the initial upward-concave curvature of the mirror layer to a downward-concave curvature.

5. The device of claim 1, wherein the mirror stage further comprises a tensile stress layer between the membrane layer and the mirror layer, the tensile stress layer being configured to impart an initial upward-concave curvature to the mirror layer.

6. The device of claim 1, wherein the mirror stage further comprises a tensile stress layer on an upper surface of the mirror layer, the tensile stress layer being configured to impart an initial upward-concave curvature to the mirror layer.

7. The device of claim 1, wherein the mirror stage further comprises a compressive stress layer on an underside of the membrane layer, the compressive stress layer being configured to impart an initial upward-concave curvature to the mirror layer.

8. The device of claim 1, wherein a first conductive routing path is configured to deliver the first voltage to the membrane layer via a metal trace on the frame, a contact extending through a top oxide layer, the first flexure, and a vertical interconnect extending through a buried oxide layer to the mirror post mount that is electrically coupled to the membrane layer.

9. The device of claim 1, wherein a second conductive routing path is configured to deliver the second voltage to the bottom electrode via a metal trace on the frame, a contact extending through a top oxide layer, the second flexure, and one or more vertical interconnects extending through a buried oxide layer.

10. An adjustable-curvature micro-electro-mechanical systems (MEMS) mirror device comprising:
a frame;
a mirror stage coupled to the frame via a plurality of flexures including a first flexure and a second flexure, the mirror stage comprising a membrane layer and a mirror layer disposed on the membrane layer;
a plurality of first fingers extending outwardly from the membrane layer;
a mirror post mount and a mirror post extending from the mirror post mount, the mirror post mount and the mirror post supporting the mirror stage;
a comb mount surrounding the mirror post mount;
a plurality of second fingers extending inwardly from an upper portion of the comb mount and interdigitated with the plurality of first fingers to form a comb-finger actuator;
wherein the first flexure is electrically coupled to the membrane layer and the plurality of first fingers;
wherein the second flexure is electrically coupled to the comb mount and the plurality of second fingers; and
wherein a first voltage supplied to the first flexure and a second voltage supplied to the second flexure are routed through mutually isolated conductive paths such that the first voltage is insulated from the second voltage.

11. The device of claim 10, wherein each of the plurality of first fingers and the plurality of second fingers has a width between approximately 1.5 μm and 3.0 μm and a gap between adjacent ones of the plurality of first fingers and the plurality of second fingers between approximately 2.0 μm and 3.0 μm.

12. The device of claim 10, wherein a thickness of the plurality of second fingers corresponds to a thickness of a device layer of a silicon-on-insulator wafer.

13. The device of claim 10, wherein a thickness of the plurality of second fingers corresponds to a thickness of an upper portion of a device layer of a silicon-on-insulator wafer.

14. The device of claim 10, wherein the plurality of second fingers, the plurality of first fingers, and the membrane layer each has substantially the same thickness.

15. The device of claim 10, wherein the membrane layer has an initial upward-concave curvature with a radius of curvature between approximately 10 mm and 15 mm such that the plurality of first fingers is vertically offset relative to the plurality of second fingers by approximately 0.5 μm to 2 μm.

16. The device of claim 10, wherein the plurality of first fingers and the plurality of second fingers are arranged to surround at least a substantial portion of an outer perimeter of the membrane layer and a corresponding inner perimeter of the comb mount.

17. The device of claim 10, wherein, when the first voltage and the second voltage establish a potential difference between the plurality of first fingers and the plurality of second fingers, an electrostatic force generated between the plurality of first fingers and the plurality of second fingers displaces the membrane layer to reduce an initial upward-concave curvature of the mirror layer and/or to change the initial upward-concave curvature of the mirror layer to a downward-concave curvature.

18. The device of claim 10, further comprising a tensile stress layer disposed between the membrane layer and the mirror layer, the tensile stress layer being configured to impart the initial upward-concave curvature to the mirror layer in the absence of actuation of the comb-finger actuator.

19. The device of claim 10, wherein the mirror stage further comprises a tensile stress layer on an upper surface of the mirror layer, the tensile stress layer being configured to impart an initial upward-concave curvature to the mirror layer.

20. The device of claim 10, wherein the mirror stage further comprises a compressive stress layer on an underside of the membrane layer, the compressive stress layer being configured to impart an initial upward-concave curvature to the mirror layer.

21. An adjustable-curvature micro-electro-mechanical systems (MEMS) mirror device comprising:
a frame;
a mirror stage coupled to the frame via a plurality of flexures including a first flexure and a second flexure, the mirror stage comprising a membrane layer and a mirror layer disposed on the membrane layer;
a plurality of first fingers extending outwardly from the membrane layer;
a mirror post mount and a mirror post extending from the mirror post mount, the mirror post mount and the mirror post supporting the mirror stage;
a comb mount surrounding the mirror post mount;
a plurality of second fingers extending inwardly from an upper portion of the comb mount and interdigitated with the plurality of first fingers to form a comb-finger actuator; and
a parallel plate assistance electrode surrounding the mirror post mount and disposed beneath at least a portion of the membrane layer;
wherein the first flexure is electrically coupled to the membrane layer and the plurality of first fingers;
wherein the second flexure is electrically coupled to the parallel plate assistance electrode, the comb mount, and the plurality of second fingers; and
wherein a first voltage supplied to the first flexure and a second voltage supplied to the second flexure are routed through mutually isolated conductive paths such that the first voltage is insulated from the second voltage.

22. The device of claim 21, wherein the parallel plate assistance electrode comprises a hollow peripheral body surrounding the mirror post mount and defining an inner opening in which the mirror post mount is disposed.

23. The device of claim 21, wherein the parallel plate assistance electrode includes a main body underlying an outer region of the membrane layer and a plurality of protrusions extending radially outward to underlie respective ones of the plurality of first fingers.

24. The device of claim 21, wherein an upper surface of the parallel plate assistance electrode is spaced from an underside of the membrane layer by a gap selected such that, when the second voltage is applied to the parallel plate assistance electrode and the first voltage is applied to the membrane layer, an electrostatic parallel-plate force is generated that cooperates with an electrostatic comb-finger force between the plurality of first fingers and the plurality of second fingers to displace the membrane layer so as to (i) reduce an initial upward-concave curvature of the mirror layer and/or (ii) change the initial upward-concave curvature of the mirror layer to a downward-concave curvature.

25. The device of claim 21, wherein the parallel plate assistance electrode and the comb mount are electrically common and are driven at a same potential via the second flexure.

26. The device of claim 21, wherein geometry and spacing of the parallel plate assistance electrode under the membrane layer are configured such that, at an intermediate actuation level at which the mirror layer is substantially flat, the parallel-plate contribution from the parallel plate assistance electrode provides a dominant portion of a net electrostatic force acting on the membrane layer.

27. The device of claim 21, further comprising a tensile stress layer disposed between the membrane layer and the mirror layer, the tensile stress layer being configured to impart the initial upward-concave curvature to the mirror layer.

28. The device of claim 21, wherein the mirror stage further comprises a tensile stress layer on an upper surface of the mirror layer, the tensile stress layer being configured to impart an initial upward-concave curvature to the mirror layer.

29. The device of claim 21, wherein the mirror stage further comprises a compressive stress layer on an underside of the membrane layer, the compressive stress layer being configured to impart an initial upward-concave curvature to the mirror layer.

30. A method of fabricating a micro-electro-mechanical systems (MEMS) array, the method comprising:
forming first etched regions on a first wafer;
forming partially etched regions on a second wafer;
bonding the second wafer to the first wafer;
removing at least a portion of the second wafer;
forming isolation trenches in the first wafer;
filling the isolation trenches with dielectric material;
forming vias in the first wafer;
depositing a first metal layer on the first wafer;
depositing a second metal layer on the first wafer to form a reflective surface;
etching the first wafer to form blades;.
bonding a base wafer to the first wafer; and
forming release trenches in the first wafer to release MEMS structures.

31. The method of claim 30, wherein the first wafer and the second wafer are silicon-on-insulator (SOI) wafers.

32. The method of claim 30, further comprising depositing a stress layer on selected regions of the first wafer.

33. The method of claim 30, further comprising bonding a lid wafer to the first wafer after forming the release trenches.
